(19) United States
(12) Patent Application Publication
(10) Pub. No.: US 2009/0165876 A1
(43) Pub. Date: Jul. 2, 2009

(54) Microfluidic Structures

(76) Inventors: Micah James Atkin, Victoria (AU); Gregory Francis Eaton, Victoria (AU)

Correspondence Address: CLARK & ELBING LLP, 101 FEDERAL STREET, BOSTON, MA, 02110, US

(21) Appl. No.: 12/085,251

(22) PCT Filed: Nov. 22, 2006
(86) PCT No.: PCT/IB2006/003311

§ 371 Date: Dec. 30, 2008

Related U.S. Application Data
(60) Provisional application No. 60/738,609, filed on Nov. 22, 2005.
(60) Provisional application No. 60/738,610, filed on Nov. 22, 2005.
(60) Provisional application No. 60/738,611, filed on Nov. 22, 2005.
(60) Provisional application No. 60/738,612, filed on Nov. 22, 2005.
(60) Provisional application No. 60/786,715, filed on Mar. 29, 2006.

(30) Foreign Application Priority Data
Nov. 22, 2005 (AU) 2005906474
Nov. 22, 2005 (AU) 2005906475
Nov. 22, 2005 (AU) 2005906476
Nov. 22, 2005 (AU) 2005906477
Jun. 7, 2006 (AU) 2006903101

(51) Int. Cl. B81B 3/00; F15C 1/04

(52) U.S. Cl. 137/825; 137/833; 137/832

(57) ABSTRACT

A fluid handling structure includes: an actuation area (03, 08) to control fluid flow within the structure; and a plurality of actuation components (09, 11, 12, 13) within the actuation area (03, 08); wherein the actuation area (63, 68) is constructed and arranged to activate or control each of the plurality of actuation components (09, 11, 12, 13). A fluid handling structure comprising: a fluid channel (204); and a deformable material (202); wherein the fluid channel is bounded, at least in part, by the deformable material (202). A fluidic device comprising: at least one channel (403) defining a path for the travel of an electromagnetic wave. A method of performing a function with an instrument, the method comprising: associating an insert with the instrument, the insert comprising one or more of program code, data, or commands, which enable performance of the function.

### FIELD OF THE INVENTION

This invention relates generally to structures, devices and methods for manipulating fluid flow, optionally within structures with at least one dimension generally less than ten millimeters in size but usually less than one millimeter. More particularly, the present invention relates to a variety of fluid-handling structures allowing external manipulation of fluids within a device. A single actuator may act upon more than one fluid-handling structure. The fluid handling strategies may involve the use of moveable components, electrodes, and semi-permeable membranes or combinations thereof. The deformable components may be deformed directly into a fluid-handling structure, or indirectly act upon part of a fluid handling structure, to cause or prevent a change in pressure or shape within the fluid-handling component Gas permeable membranes can be used to restrict fluid flow within some structures for pumping, valving, chemical storage and injection, filtering, or degassing.

This invention also relates generally to structures, devices and methods for manipulating fluid flow, optionally within structures with at least one dimension generally less than ten millimeters in size but usually less than one millimeter, using deformable or moveable components. More particularly, the present invention relates to fluid-handling structures containing deformable components that may be used as pumps or valves. The deformable component may act in a variety of ways, for example it may be deformed into a fluid-handling structure, or act upon part of a fluid handling structure, to produce a restriction of flow or an increase in pressure or induce flow in the fluid contained therein.

This invention additionally relates generally to devices and methods for fabricating flow cells for measurements in devices containing structures for fluid flow, optionally with at least one dimension generally less than ten millimeters in size but usually less than one millimeter. More particularly, the present invention relates to sub-millimeter devices and structures to facilitate the measurement of the electromagnetic wave interaction with fluids flowing therein and methods of manufacturing these devices and structures.

This invention also relates generally to systems and methods for software and data handling, and more particularly, to a system and methods for upgrading, configuring or passing information to a device through the use of one or more inserts that may be used primarily for other purposes.

### BACKGROUND OF THE INVENTION

In the discussion that follows, reference is made to certain structures and/or methods. However, the following references should not be construed as an admission that these structures and/or methods constitute prior art. Applicant expressly reserves the right to demonstrate that such structures and/or methods do not qualify as prior art.

### Articles and Methods for Fluid Manipulation

There has been increasing interest in the development of microscale systems for fluid analysis. These developments have been brought about by the advantages that miniaturization has to offer. In particular, performance improvements can be achieved over traditional laboratory equipment in terms of automation, reproducibility, speed, cost and size. This rapidly growing field includes micro total analytical systems (μTAS), or “lab on a chip” devices. Much of this early work was performed on silicon or glass substrates using established techniques developed in the 70's and 80's for the semiconductor industries.

There have been many different pumping and valving strategies that have been integrated into miniaturized devices. The simplest of which is capillary wicking, where the surface tension enables fluid flow in a suitable capillary environment. Unfortunately, this technique has only limited capacity for sample introduction in appropriately shaped capillaries. Electrokinetic flow is another popular technique but is limited in substrate and fluid medium choice, due to surface charge interactions with the fluid and joule heating, and use high driving voltages that are potentially dangerous for many portable diagnostic applications. Electrokinetic flow can also be used to induce flow in connecting channels that do not undergo electrokinetic pumping, see U.S. Pat. No. 6,012,902; however the same electrokinetic limitations still apply to the electro-active region and systems driving voltage.

In terms of versatility the pressure driven pump is a preferred method for fluid transport. However, to date pressure pumps integrated into microdevices have required relatively complex instrumentation systems to control actuators that operate the micropumps. Examples of this type of approach can be seen with the pneumatic operation described in U.S. Patent Publication Nos. US2002/0148992, U.S. Pat. No. 6,619,311, US2004/0209354A1, and U.S. Pat. No. 6,408,878, and the piezo driven micropumps of U.S. Pat. No. 6,073,482. In many cases this instrumentation requirement limits the device's use to that which complies with the size and cost constraints of the supporting instrumentation. Another inherent problem in the operation of known devices is the inherent inefficiency and reliability of the fluid-handling operations. Channels with deformable membranes are prone to leakage due to the need to conform the movable components to the channel dimensions. Furthermore, complex manifolds and large areas on the microdevice are required for complex fluid manipulation.

In addition, pressure pumps integrated into microdevices have typically involved complex three dimensional geometries with multiple one-way valves that are complex to manufacture and have resulting reliability problems. Examples of these types of geometries in polymer materials can be seen with U.S. Pat. Nos. 5,718,567 and 6,073,482. Similar three dimensional membrane-based valve topologies have been demonstrated in multilayer polymer films by U.S. Pat. No. 6,619,311 and U.S. Patent Application Publication US2002/0148992A1. However, the overall relative complexity of the structures and requirement for pneumatic operation introduce difficulties with bonding and interfacing, and their use is restricted to applications where a pneumatic supply can be provided.

A simpler valve design is provided with U.S. Pat. No. 6,408,878 which involves microfluidic channels cast inside an elastomer. A second channel or structure is required within the elastomer to allow deflection upon actuation into the first channel, typically by pneumatic force. This technique is not suited to mass production due to the requirements of forming microstructures within the elastomer, i.e.—the proposed multi-step casting method is a slow batch-based process.

Traveling wave type pumps have been fabricated in miniaturized silicon devices using an electrically deformable membrane, see U.S. Pat. Nos. 5,705,018 and 5,096,388. However due to the materials used, and the special processing requirements, the manufacturing methods are limited to batch-based semiconductor fabrication processes, which are relatively expensive. U.S. Pat. No. 6,408,878 discloses a polymer multi-valve pump that produces a peristaltic type motion by using three or more valves that alternately deform into a fluid channel to give a pseudo traveling wave, but the fabrication is also limited to batch-based processing.

What is required for many portable and low-cost applications are methods of improving device efficiency, and simplifying or reducing the size and cost of the supporting instrumentation. The devices and methods described in the prior art do not provide a method for small scale pumping, valving, and other fluid manipulation that is efficient, simple to use, small, lightweight, intrinsically reliable or scaleable for high throughput mass production.

### Optical Measurement Devices and Methods

Critical to the usability of microfluidic devices is the ability to analyze the characteristics of the fluids so contained. Many methods and techniques are used to measure these characteristics including electromagnetic radiation interaction such as optics and detection strategies for the same. Such absorption, transmission and luminescence (phosphorescence and fluorescence) based measurements present difficulties at the small scale used in these devices. Most of these difficulties arise from the tight dimensional constraints, reduced path length, and reduced fluid volumes leading to much smaller signal responses.

Capillary or microfluidic optical based detection techniques have typically employed instruments containing their own wave interaction elements to focus photons into the small chambers or channels of the fluidic devices. Problems with these techniques include: alignment difficulties due to the small fluidic dimensions; the size of the components used; and in cases such as fluorescence, signal losses due to the distance from the fluidic source of the focusing optics and their focusing area. Another approach that improves on some of these aforementioned limitations, is to incorporate optical elements in the same part as the fluidic elements.

An example of a microfluidic device with integrated optical components is described in U.S. Pat. No. 6,100,541. Here optical components are integrated into the body structure adjacent to the microchannels inside the body structure. A polymeric structure with an integrated lens adjacent to a microfluidic channel is described.

For measuring bulk fluid changes in such small dimensions (generally less than 10 mm) it is commonly understood that increasing the path length can improve detector response. In cases of transmission or absorption-based detection, the signal response is proportional to the path length through the fluid (Beer's Law). Likewise, a better signal can be produced with more light emitting reporters as can be used with luminescence measurements. For example, in capillary electrophoresis, improved detection has been demonstrated with an increased optical path length using a “Z cell” configuration.

Increased path length detector cells have been demonstrated in microfluidic devices using optical fiber coupling and silicon or glass etching techniques. These are typically expensive fabrication processes that do not lend themselves to high volume manufacture of disposable devices. Examples of such devices are disclosed in U.S. Pat. Nos. 5,599,503 and 6,490,034, which provide methods for fabricating microfluidic devices with a detector cell for the absorption of UV or visible radiation. The inlet and outlet radiation is redirected along the channel of the microfluidic device by reflection from the angled inlet and outlet walls with (U.S. Pat. No. 5,599,503) or without (U.S. Pat. No. 6,490,034) multiple reflections. The systems described are fabricated using silicon etching techniques. However, silicon based fabrication of disposable microfluidic devices is commercially challenging, particularly in the intrinsically high unit price and significantly low unit volumes with this particular substrate family.

An alternative approach to passing the light radiation longitudinally along the channel axis is disclosed in U.S. Pat. No. 6,224,830. The device described produces multiple passes across a fluidic channel for increased absorption in a small detector region (less than 200 μm). However, a fundamental problem with this technique is the photon energy losses incurred from multiple reflections and material boundary transitions limiting the size and sensitivity of the fluid detection cell.

A common approach to couple the light to fluidic devices is to employ optical fibers that are directly interfaced to the fluidic manifolds. These manifolds are typically machined from a single bulk material and are therefore very limited in their geometry. Microfluidic devices are typically made from multiple layers of materials forming complex fluidic manifolds. This multilayer design introduces coupling and alignment difficulties when coupling optical fibers to fluidic circuits. An approach proposed for polymer based microfluidic devices is disclosed in U.S. Pat. No. 6,867,857 and involves coupling a multilayer fluidic device to an external flow cell with fiber optic ports. However, this approach employs separate fabrication processes for each part and introduces alignment or dead volume difficulties, and adds to both the device's size and the unit cost.

A similar approach to the silicon based reflectors described earlier is provided in U.S. Pat. No. 6,900,889 where polymer microfluidic devices for fluorescent point source detection is disclosed. The disclosed method passes a laser along a trajectory, traversing the length of a micro channel, in order to excite fluorescent markers in the fluids contained in a polymer microfluidic device. Light emitted from the markers is then detected through the micro channel's cover. This technique obviates the need for a laser beam to scan along a channel to find the fluorescent marker. However this method employs a light directing member, or reflective surface, that is separate from the microfluidic device. Furthermore the device is unsuitable for transmission and absorption based measurements as it does not provide a mechanism for recovering or measuring the light characteristics after it has traversed through the sample fluid. Another limitation is that the system only provides for detection of point sources (reporters) radiating perpendicular to the fluidic channel. This further limits the technique as the point source signal response is low and there is no ability to increase the signal (and therefore the sensitivity), by concentrating the light.

U.S. Pat. No. 6,906,797 describes polymer microfluidic devices with reflective channels for guiding light across a multiplicity of channels for the purposes of fluorescent point detection. Due to measurement across the width of the channels this technique is limited in its signal response in a similar manner to the previous example and further optical losses are encountered as the light passes the different media due to the separation of the light and fluidic channels. Furthermore there is no method for concentrating the emitted signal from the point sources.

The devices and methods described above in the prior art do not provide a low cost integrated approach for adequate absorption, transmission, and luminescent detection in microfluidic devices. The current invention fulfils the need for low cost polymeric devices with increased optical performance inside flow cells that are intrinsically reliable and scaleable for high throughput mass production.

### Methods of Instrument Configuration

Instruments of many different descriptions are known. For example, certain types of instruments are devices that control experiments or collect information from an environment, unit or material(s) being tested. Other instruments may perform data analysis or processing of data, including display to the user and or storage of data. Examples of instruments include digital multimeters, oscilloscopes, DNA sequencers, pressure sensors, temperature sensors, pH sensors, but may also include any device which is operable with an insert, and for example may include mobile telephones, computers, personal digital assistants (PDAs), digital music players, etc.

An insert is a removable or connectable device that may be a sensor, cartridge or cassette, such as a microfluidic device, that works in association with an instrument, for example by providing some functionality to it. The insert may for example be a memory stick, smart card, or a rigid or flexible printed circuit.

Inserts are usually designed for a specific purpose or purposes such as metabolite monitoring in whole blood, electrochemistry performed on mineral samples or DNA amplification from bacteria, to name only a few such specific purposes. If the instrument is dedicated to that particular application and sensor type then all necessary program operation routines, or experimental protocols, can be contained within the instrument and no on-chip recognition is required to distinguish between the insertable devices as they are all the same.

However when multiple insert types are used in the same instrument then the instrument must distinguish between each one, so that the correct protocols are performed physically, chemically and or electronically on the insert and/or its contents.

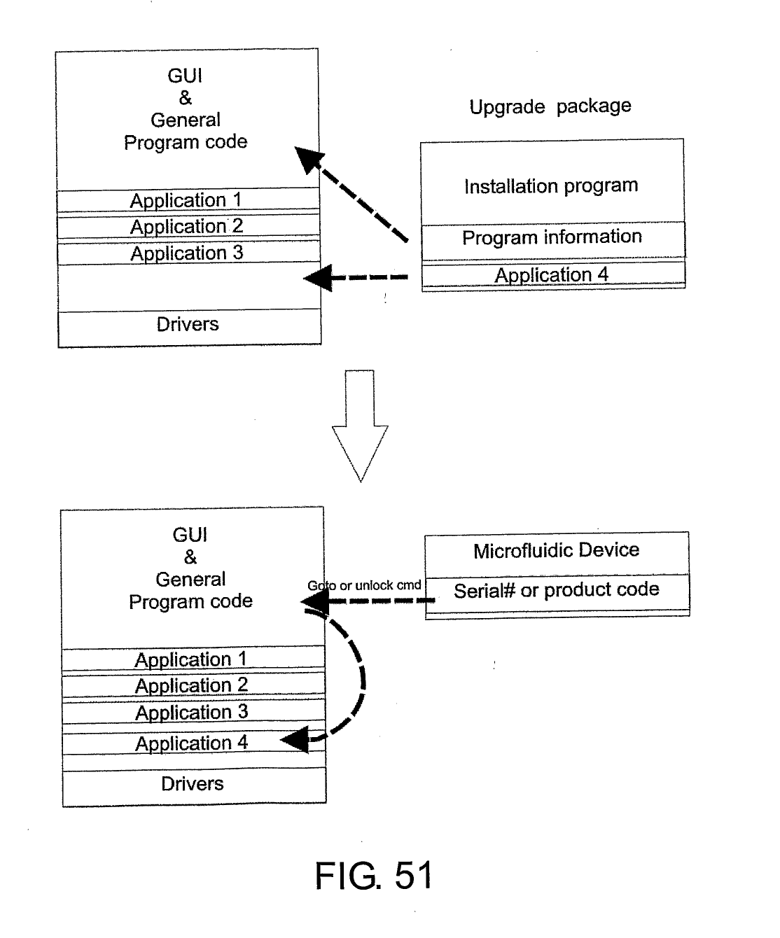

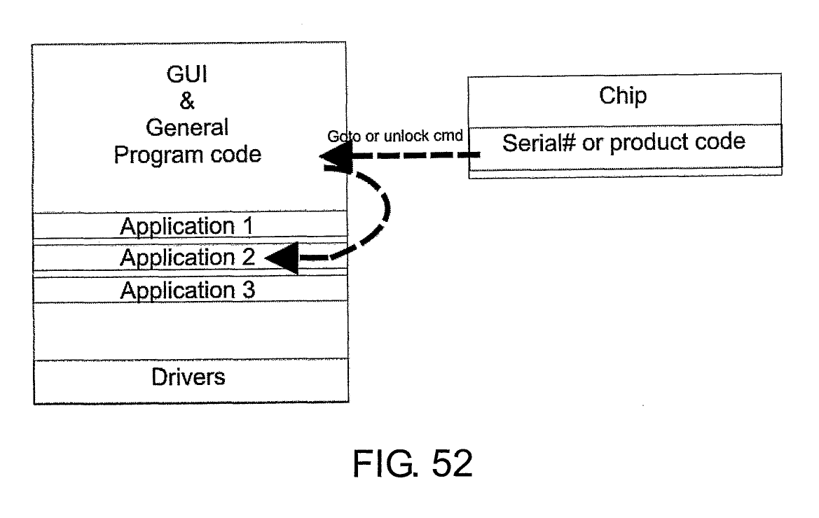

Generally, either the user selects which inserts are in use or manually configures the instrument for use with each insert. Alternatively, the insert itself indicates to the instrument its function. This has been traditionally achieved through the use of serial or product numbers, which the instrument then references within its own internal programming code to establish the appropriate application protocols to be used with a particular insert type (e.g., FIGS. 51 and 52). Traditionally this kind of information has been encoded in many different formats, including: electrically by electrode connections, resistor values, or integrated circuits; optically by barcode; magnetically by magnetic strip and mechanically. For microfluidic inserts the standard methods of encoding information to indicate chip functionality to an instrument is described in U.S. Pat. No. 6,495,104.

The disadvantage of this kind of indication is that the instrument software is still required to contain all the program information for the device's operation. The instrument therefore needs to either contain all coding for all possible applications before it leaves the manufacturer, or after sales software upgrade packages need to be supplied with each new application. Similar after sales support is required in the form of software upgrades for software bug fixes and, as is often the case with scientific instruments, new calibration or operational data.

Traditionally, these upgrades have been provided to the user as new software versions or as service pack upgrades on disks or CD-ROMs. This is typically only done for major revisions or upgrades, as frequent distribution of upgrade media and the user action required to install the upgrades is considered problematic. With the development of world-wide-web installation, upgrades can be performed remotely, but only if the instrument is connected to an appropriate network.

A further disadvantage of providing individual upgrades for new instrument applications is the development cost in providing the new application routines and relevant installation package. This method of upgrade also tends to introduce further possibilities for program error or system hang-ups due to the increase in the inherent complexity of the software code and the potential incompatibilities caused by numerous revisions and incomplete sequence history. In addition, allowing an instrument to be upgraded this way leaves it open to unauthorized “hacking” which introduces further reliability and warranty problems for the manufacturer or reseller.

Furthermore, there are extra logistical concerns relating to cost and technical problems with the delivery of the upgrade service, whether it be a physical disk or remotely by methods including email and the internet.

A disadvantage of the prior art method of keeping the full program coding on the instrument is the inherent security risk of containing all the instrument's operational protocols in one program. Placement of the instrument's program operation entirely in the instrument, means that reverse engineering is potentially easier, allowing unauthorized usage of the instrument and or operation with third party inserts or even duplication of an entire instrument.

Traditional methods of software protection include the use of serial numbers, remote license servers and/or files, and dongle protection. Unfortunately, these methods do not stop a skilled operator from accessing the onboard application program to operate the instrument or use foreign inserts. One such example of bypassing a program's authorization code is to ‘hack’ into the program and bypass the authorization code query, allowing full program operation without authorization.

The present invention describes new methods and systems to overcome the above-mentioned limitations by ensuring that some or all of the upgrade data, program code, experimental data, or related information is kept within the insert.

### SUMMARY OF THE INVENTION

### Articles and Methods for Fluid Manipulation

According to a first aspect of this invention, there is provided a fluid handling structure comprising: an actuation area to enable control of fluid flow within the structure; and at least one actuation component within the actuation area; wherein the actuation area is arranged to activate or control the at least one actuation component. In some embodiments, the actuation area comprises a controller to control fluid flow within the device.

In another embodiment, there is provided a microfluidic device comprising a controller to control fluid flow within the device wherein the controller is capable of simultaneously activating more than one pumping and/or valving component associated with fluid flow within the device.

According to one embodiment, the controller is manually or pneumatically operable. However, any suitable means of operation may be used. For example, the controller may be operable electromagnetically, mechanically, hydraulically, by acoustics, or by piezo electrics, etc.

According to a second aspect of this invention, there is provided a fluid handling structure comprising: an actuation area to enable control of fluid flow within the structure; at least one of a fluid chamber or channel; a semi-permeable membrane forming at least one boundary of the fluid chamber or channel, the semi-permeable membrane arranged so as to permit the passage of a control fluid therethrough and into the fluid chamber or channel, thereby promoting, restricting, or stopping fluid flow within the fluid chamber or channel. The control fluid may comprise any suitable fluid and may also for example be a liquid, a gas, or combinations thereof. One embodiment comprises a second semi-permeable membrane forming at least a second boundary of the fluid chamber, channel, or fluidic network. It is not necessary that the second boundary be in direct communication with the fluid chamber or channel. For example, it may be further along the fluidic network.

In another embodiment, there is provided a microfluidic device comprising a semi-permeable membrane which restricts passage of fluid and/or particles therethrough. According to this aspect of the invention passage of fluid (such as gas or liquid) or particles may be delayed or blocked. A membrane according to this aspect of the invention may be adapted to provide functions such as separation, de-bubbling, filtering, pumping, valving, mixing, priming, dosing, etc. For example, according to one embodiment, a fluid is unable to pass through the membrane until a certain internal pressure is reached at which time the fluid will pass through the membrane. This particular embodiment is useful for sample storage and injection, pumping, and valving.

According to another embodiment, the membrane allows gas to pass through but not liquid (which is blocked) for functions such degassing, pumping, valving, reagent storage and injection. According to another embodiment, the membrane filters particles in the fluid. Such particles might for example include cells, micro-organisms, macromolecules, antigens etc.

According to another embodiment, a recirculating fluidic network is provided. The recirculating fluid network may for example comprise an inlet; at least one of a pump or valve or a debubbler. A recirculating fluid network may also comprise a detection chamber. In some embodiments, the inlet port may in addition function as a debubbler.

According to another embodiment the instrument-card interface is configured such that the card provides some of the pneumatic plumbing. According to another embodiment the pumps and valve controllers are driven from the same pressure reservoir.

Fluid pumping, valve control, degassing, filtering, sample introduction, reagent-storage and controlled dosing are useful in performing complex chemical protocols. A common problem in microfluidics is the transport of fluids in accurate but very small quantities. The present invention comprises a variety of fluid-handling structures containing moveable components, semi-permeable membranes, electrodes, or combinations thereof. By providing a controller which is capable of simultaneously activating more than one component, it is possible to simplify device operation, and thereby instrumentation requirements for fluid handling components. The actuation may be performed manually directly by the user or with the aid of an instrument. Methods for overcoming priming, sample introduction, injection, reagent storage, mixing and bubble problems are also disclosed as part of the invention.

According to another aspect of the invention, there is provided a fluid handling structure comprising: a fluid channel; and a deformable material; wherein the fluid channel is bounded, at least in part, by the deformable material, and the deformable material is arranged to produce a restriction, or point of compression within the channel. In some embodiments, the restriction may optionally enable the creation of a traveling fluid wave within the channel. The structure may further comprise a rigid substrate wherein the fluid channel is formed, at least in part, within the rigid substrate.

In another embodiment, there is provided a device comprising a channel defined at least partially by a deformable material wherein deformation of the deformable material is capable of creating a traveling fluid wave within the channel. According to one embodiment of this aspect of the invention, the device is a microfluidic device.

According to a further embodiment of this aspect of the invention, the fluid wave is created by applying a force to the fluid at a single location along the channel at any instant in time. According to another embodiment of this aspect of the invention, the device is a microfluidic device which is not made from silicon. Preferably, it is a laminar microfluidic device, and preferably it does not utilize an electromagnetic mechanism to create the fluid wave.

According to a further aspect of the invention, there is provided a method of pumping fluid in a channel in a microfluidic device comprising utilizing a deformable material to produce a traveling fluid wave within the channel.

According to an additional aspect of the present invention, there is provided a microfluidic device comprising a microfluidic channel defined at least partially by a deformable material wherein the cross-sectional area of the deformable material is substantially larger than that of the channel and the deformable material is sufficiently deformable such that it is able to at least partially enter the channel and thereby affect fluid flow within the channel. Deformable material according to this aspect of the invention may be of any suitable type. A skilled worker will readily be able to identify appropriate materials. For example, certain elastomeric compositions have the appropriate characteristics.

Deformable materials include, but are not limited to, polymers, polymer composites, metals and glasses. Where the deformable material is too rigid to deform sufficiently then the deformable material is structured to allow deformation, and/or combined with or replaced by other materials that have more suitable elastomeric properties, such as rubbers, Santoprene™, poly(dimethylsiloxane), Nitriles, polyurethanes, silicons, polyisoprene, polybutadiene, polychloroprene, polyisobutylene, poyl(styrene-butadiene-styrene), etc.

Use of a deformable material capable of creating a traveling fluid wave within the channel provides a simple geometry that enables the required accurate fluid delivery and at the same time facilitates low cost mass production. Furthermore, the present invention enables a more economical division between the costly actuator components and low cost fluid handling components. According to one preferred embodiment, the actuating component is external to the fluid-handling device that contains a deformable material. A fluid-handling device according to the present invention may be fabricated from polymeric material and produce fluid flow by causing all or part of the fluid-handling component to deform, to, e.g., restrict, pressurize, or induce fluid flow.

As used herein, the term “fluid” refers to either gas or liquid phase materials.

As used herein, the term “actuation area” refers to the area on the fluid-handling device upon which an actuator acts.

### Optical Measurement Devices and Methods

The present invention also provides methods and devices for systems incorporating flow cells with longitudinal optical paths (for example, microfluidic systems). In particular, devices and methods are provided for passing light longitudinally along a channel and for deliberate concentration of exiting light and thereby and through various other means, herein described, improve the signal response and therefore the sensitivity of a selected measurement system.

Accordingly, in one aspect of the invention, there is provided a fluidic device comprising: at least one channel defining a path for the travel of an electromagnetic wave. In some embodiments, the path is substantially longitudinal for at least a portion of the length of the channel. In some embodiments, the path is substantially perpendicular, or transverse, to at least a portion of the length of the channel. In other embodiments, the path is substantially perpendicular, or transverse, to at least a portion of the length of the channel. The electromagnetic wave may comprise at least one of: visible light, ultraviolet light, microwaves, radio waves, x-rays, and gamma rays.

In another aspect of the invention, there is provided a device comprising a channel adapted for electromagnetic wave-based measurement of characteristics of a fluid within the channel wherein the measurement can be undertaken by causing the electromagnetic wave to travel substantially longitudinally along at least part of the channel.

According to one embodiment, the electromagnetic wave is visible light. However, any form of electromagnetic wave may be used which is suitable for the purpose. Thus, for example ultraviolet or infrared light, microwaves, radio waves, x-rays, may be used, and so may gamma rays.

A device according to the present invention may be used for any suitable purpose involving optical sensing. According to one embodiment, the device is for microfluidic applications.

According to a further embodiment, the device is a microfluidic device and comprises layers which have been engaged (for example, bonded), so as to form the microfluidic device (a ‘laminar’ device). According to another embodiment, the device comprises at least one optical window to allow the electromagnetic wave (such as light) to enter and/or exit the channel. According to an additional embodiment, the device is not made from silicon or a silicon-based material.

In one embodiment, light enters the flow cell through an optically clear opening at one end of the channel, at which a reflective or refractive means guides the light path to one which is longitudinal along the channel or flow cell. Light levels are maintained (and losses are minimized) throughout the channel by either providing reflective surfaces, or appropriate refractive index changes to maximize total internal reflection along the length of the channel or flow cell. At the detection point a reflective and/or refractive structure guides and, if desired, concentrates the light exiting the channel for detection purposes.

In another embodiment a flow cell is provided which is capable of both longitudinal and/or transverse illumination or detection.

The methods and devices of this aspect of the invention are suitable for microfluidic devices produced by traditional batch-based and reel-to-reel fabrication processes, including but not limited to laser processing, die cutting, embossing, injection molding, and lamination methods.

As used herein, the term “microfluidic” or “fluidic” refers to fluid handling, manipulation, or processing carried out in structures with at least one dimension which may be less, than one millimeter.

As used herein, the term “light ray” refers to more than one photon of electromagnetic radiation traveling in a substantially similar direction.

As used herein, the term electromagnetic radiation refers to energy in the form of photons or waves and includes light either visible, ultraviolet, or infrared, and waves such as microwaves, radio-waves, x-rays, gamma rays and like radiation.

### Methods of Instrument Configuration

The present invention also provides methods for software or firmware upgrade, and methods for controlling an instrument, by using additional facilities within one or more removable inserts.

According to one aspect of the invention, there is provided a method of performing a function with an instrument, the method comprising: associating an insert with the instrument, the insert comprising one or more of program code, data, or commands, which enable performance of the function. The instrument may for example comprise a digital multimeter, an oscilloscope, spectrometer, chemical analysis instrument, biological analysis instrument, a DNA sequencer, a pressure sensor, a temperature sensor, a pH sensor, an electrochemical analysis device, a mobile telephone, a computer, a personal digital assistant or a digital multimedia player.

In another embodiment, there is provided a method of undertaking a function using an (i) instrument and (ii) an insert having function-specific data, comprising: (a) engaging the insert with the instrument, (b) transmitting data from the insert to the instrument, and (c) the instrument effecting the function.

According to another aspect of the invention, there is provided an insert configured for use with an instrument to perform a function, the insert comprising one or more of program code, data, or commands, which enable performance of the function. The insert may for example comprise a sensor, a cartridge, a cassette, a microfluidic device, a flash memory card, a memory stick, a smart card or a printed circuit or other memory storage component.

In another embodiment, there is provided an insert for use with an instrument to perform a function wherein the insert comprises function-specific data required by the instrument in order to effect the function.

According to a further aspect of the invention, there is provided a method of updating software or firmware of an instrument, the method comprising: associating an insert with the instrument; and transferring some or all of program code, data, or commands to the instrument thereby effecting the update. The instrument may for example comprise a digital multimeter, an oscilloscope, spectrometer, chemical analysis instrument, biological analysis instrument, a DNA sequencer, a pressure sensor, a temperature sensor, a pH sensor, an electrochemical analysis device, a mobile telephone, a computer, a personal digital assistant, or a digital multimedia player.

In another embodiment, there is provided a method of upgrading an instrument's software or firmware, wherein the instrument is for use with inserts, comprising (a) engaging an insert with the instrument, and (b) upgrading the instrument by means of data transmitted from the insert to the instrument.

According to an additional aspect of the invention, there is provided an insert for use with an instrument to perform a function wherein the insert comprises data for upgrading the instrument's software or firmware.

According to another aspect of the invention, there is provided a method of creating an interaction between an instrument and an insert having interaction-specific data, comprising: (a) engaging the insert with the instrument, (b) transmitting data from the insert to the instrument, and (c) the instrument performing a function.

Traditionally, the primary purpose of inserts is a consumable function necessary for the normal operation of the instrument. By providing additional functionality on the insert, user operation is simplified, new product development cycles are minimized, and product data security and product intellectual property are further protected. Generally, some or all of the data for an upgrade, or for the instrument operational protocols may be partially or wholly contained on one or more removable inserts according to the present invention.

The present invention provides an instrumentation and insert architecture in which one or more inserts perhaps normally used for physical functionality of the instrument, become a part of the software/firmware upgrade path for the instrument. More specifically, the insert or inserts contain some or all of the upgrade information. This approach simplifies user operation as the process of updating the software is automated; there is no need to install new software from other media. Furthermore, logistic overhead is reduced by no longer requiring the production and dissemination of separate upgrade media.

The present invention provides for program code, data, or commands to be distributed, (in ratios varying, for example from 1:0 through 1:1 to 0:1) between the instrument and one or more removable inserts. More specifically, generic subroutines may be provided on the instrument and the application specific program execution, and/or operational data, are provided on one or more removable inserts whose primary function may be as a disposable consumable to contain and perform chemical experiments or analysis on certain biological samples under the physical control of the instrument.

This distributed architecture minimizes software development associated with new application developments for an instrument and its associated inserts. The generically programmed instrument can then accept new applications without the need for the user to upgrade the software and also obviates any requirement for the application and instrument designers to anticipate new “not yet invented” applications.

The present invention provides improved user operability and operational automation by the insert providing data to the instrument to automate parts or all of the application operation and provide user defined settings. Thereby simplifying user interaction, which improves system reliability and simplifies instrument operation.

Furthermore, the invention provides extra software security as the program execution instructions do not necessarily exist in the instrument. In one particular embodiment, the insert carries the instructions to configure the instrument for the specific application of the insert. According to this embodiment, the invention produces a much more difficult path to reverse engineer, as a full understanding of the program's execution is required for successful copying. If, in the unlikely event that an instrument and an insert's interaction is finally reversed engineered, then the resultant program execution reveals only data for that specific application that the specific insert was fabricated for and no others.

The invention further allows for incremental and permanent change to the usage data contained on the insert(s) such that reverse engineered instruments are unlikely to work with new inserts.

The upgrade information, or distributed program data can be encoded onto one or more inserts and can be in many different formats including, but not limited to: electrically by electrode connections; resistor values; magnetic strips; integrated circuits; optically, and mechanically.

A further advantage of having upgrade and configuration data inside the insert(s) is the extra security feature of requiring a match between the instrument, the interface and the matching insertable device.

As used herein, and for convenience, the term “consumable insert” refers also inserts having one or more use.

As used herein the words “device” and “instrument” are interchangeable in meaning and use.

### BRIEF DESCRIPTION OF THE DRAWINGS

### Articles and Methods for Fluid Manipulation

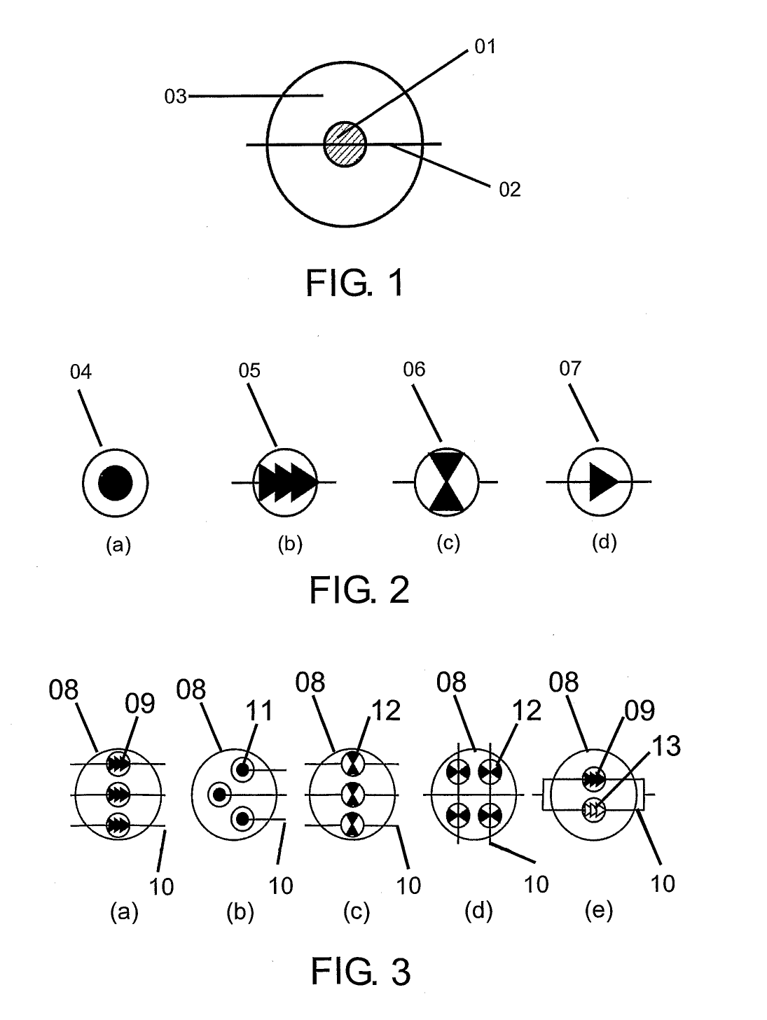

FIG. 1 is a schematic representation of an actuation area for fluid-handling. The outer circle represents the actuation area, the line through the center represents a fluid containing structure, such as a channel or pipe, and the shaded circle represents an actuator component.

FIG. 2 is a schematic representation of some of the possible actuator components. FIG. 2(a) is an injection pump, where the fluid is held within the actuator and injected through an inlet into the device upon actuation. FIG. 2(b) represents an in-line pump, which is a pump that has both an inlet and outlet. FIG. 2(c) is an ON/OFF valve or variable flow valve. FIG. 2(d) is a one-way valve.

FIG. 3 is a schematic representation of a single actuator actuating more than one actuator component. As an example, groups of three actuator components are operated from the same actuator. FIGS. 3(a), (b), and (c) represent groups of inline pumps, injection pumps, and valves, respectively, connected to individual channels. FIG. 3(d) shows an example of an alternative geometry where a single non-valved channel is intersected by two valved channels, the valves of which can be configured for fluid injection into the main channel. FIG. 3(e) represents two pumps connected in parallel operating from the same actuator, the pumps may operate in unison or in different parts of the actuation cycle.

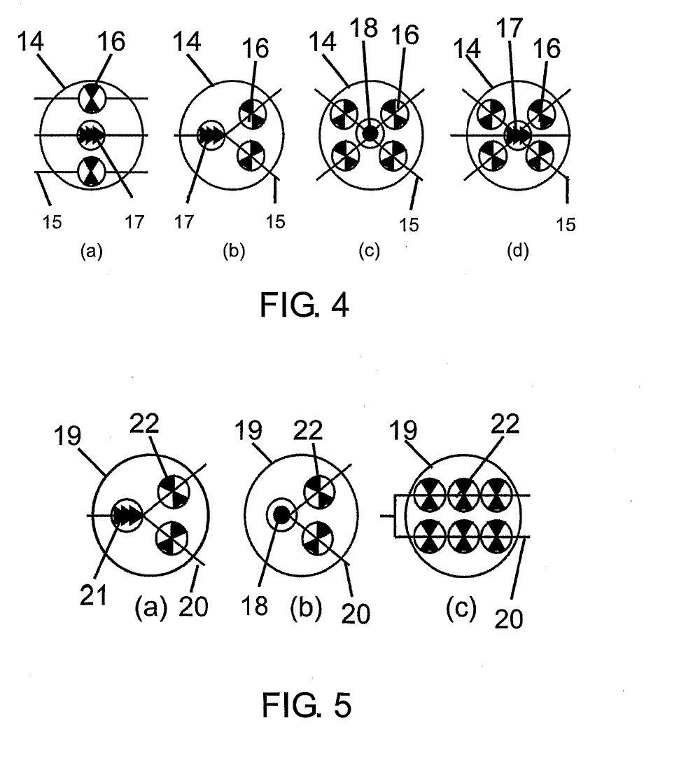

FIG. 4 is a schematic representation of a single actuator actuating more than one type of actuator component. FIG. 4(a) represents three independent channels with separate actuator components, in this case while the center channel is pumped under actuation the two outer channels are valved closed. FIG. 4(b) shows a single channel with a pump split into two valved channels. FIG. 4(c) shows an injection pump with four valved outlets. FIG. 4(d) depicts an inline pump intersecting with both valved and non-valved channels.

FIG. 5 depicts actuator components within the same channel operated by the same actuator. FIG. 5(a) shows an inline pump with downstream valves. The valves may be set to close at different points during the actuation cycle, or set to restrict the flow rate, effectively allowing a controlled volume dosing event to occur. FIG. 5(b) shows a similar controlled dosing system but using an injection pump. FIG. 5(c) illustrates an example of a peristaltic type pump configured from three differently activated valves operated by the same actuator.

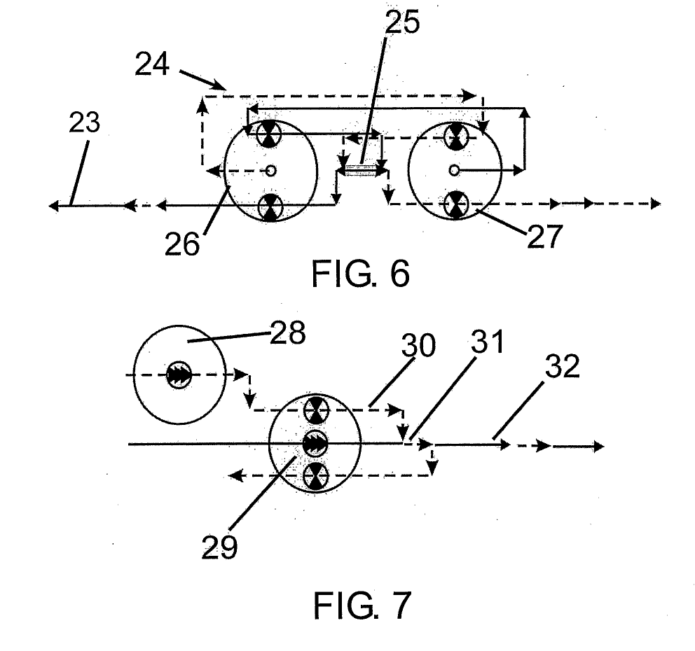

FIG. 6 illustrates a dual actuator system to inject a set volume of one stream into another fluid stream. Each stream is actuated separately to pump fluid and to valve the other stream to prevent excess flow into the other fluid system, beyond the injected volume.

FIG. 7 depicts a two actuator system similar to that depicted in FIG. 6. A set volume of the fluid, represented by the broken line, is injected into another fluid stream, represented by the unbroken line. Valving is used for only one stream as geometric structures, pressure, and surface effects can be used to preferentially guide the fluid. In this case the backpressure in the unbroken line is much higher due to a reduced cross sectional area of its channels.

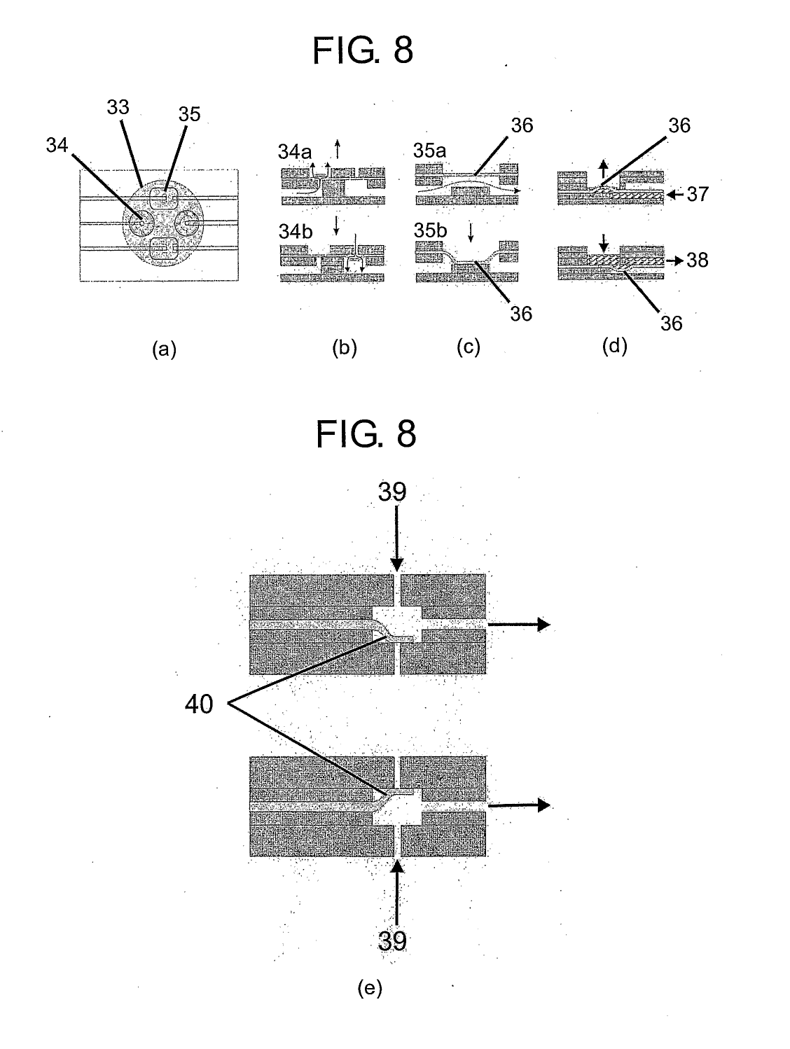

FIG. 8(a) depicts an example of an actuation area with multiple actuation components. The two center channels are connected together by the two circular one-way valves allowing a pumping action to be performed upon actuation, as shown in FIG. 8(b). The rectangular components are on/off valves that allow the deformation of a membrane to block a channel to stop flow during actuation, as shown in FIG. 8(c). FIG. 8(d) illustrates the operation of two types of valves operating as a pump, where a filling motion causes the membrane to deform upwards allowing the fluid into the pumping chamber and on the empty cycle the membrane is pushed against the base of the chamber closing the inlet slit and deforming the membrane into a lower channel, allowing the fluid to pass under the outlet restriction. FIG. 8(e) shows a three-way valve configuration where a deformable layer used to close off a particular port when pressure is applied from an opposing port.

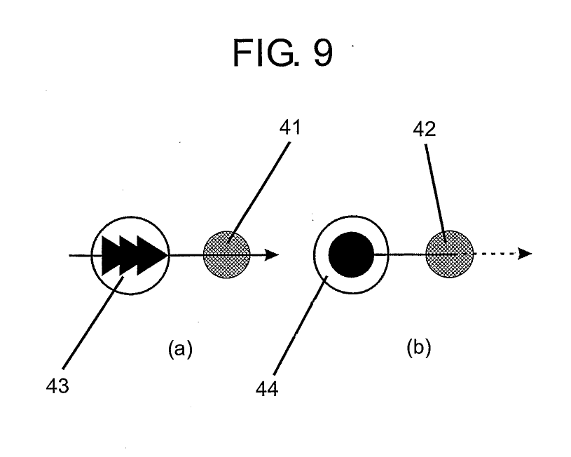

FIG. 9 is a schematic representation of pumping systems with downstream membranes for debubbling or check valves. FIG. 9(a) depicts an example of an inline pump with debubbler downstream, and FIG. 9(b) depicts an example of an injection pump with a downstream check valve.

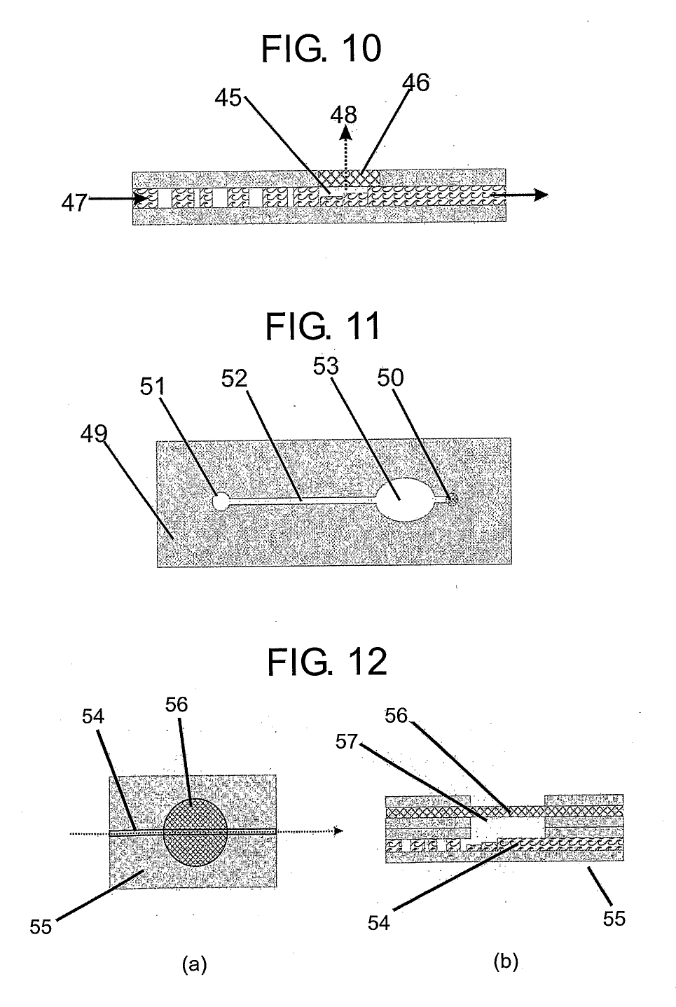

FIG. 10 is a cross section of a channel with a vent for removing gas while retaining fluid.

FIG. 11 is a top view of a substrate with a fluid inlet with a channel connecting to an oval well having an outlet to a vent for removing gas.

FIG. 12 illustrates a vent above a continuous channel. FIG. 12(a) is a top view showing a large surface area vent in comparison to the channel dimensions.

FIG. 12(b) is a transverse cross section along the channel of the same vent.

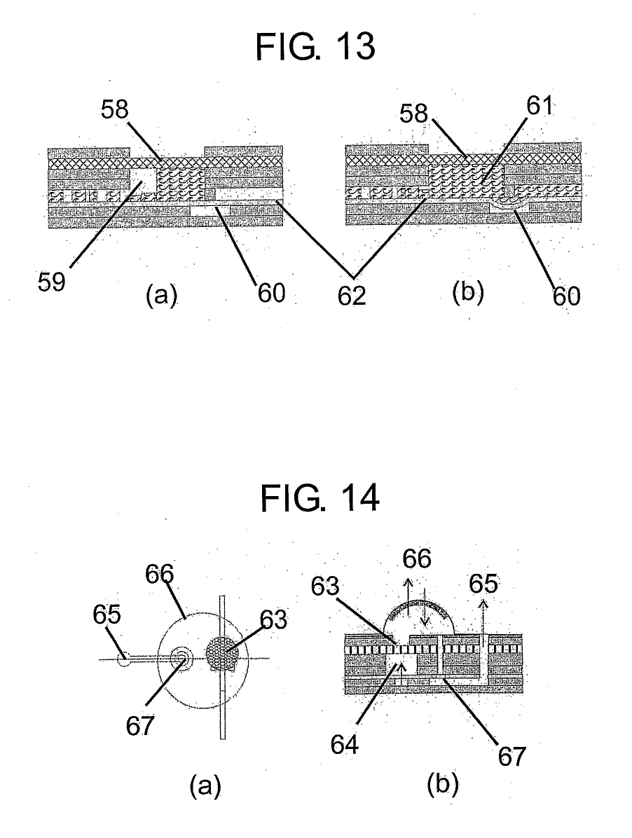

FIGS. 13(a)-13(b) illustrate the operation of a degasser where a regulation type valve is used on the outlet.

FIGS. 14(a)-14(b) illustrate combined vent and valve structures under a single actuator to effect loading of a channel/well.

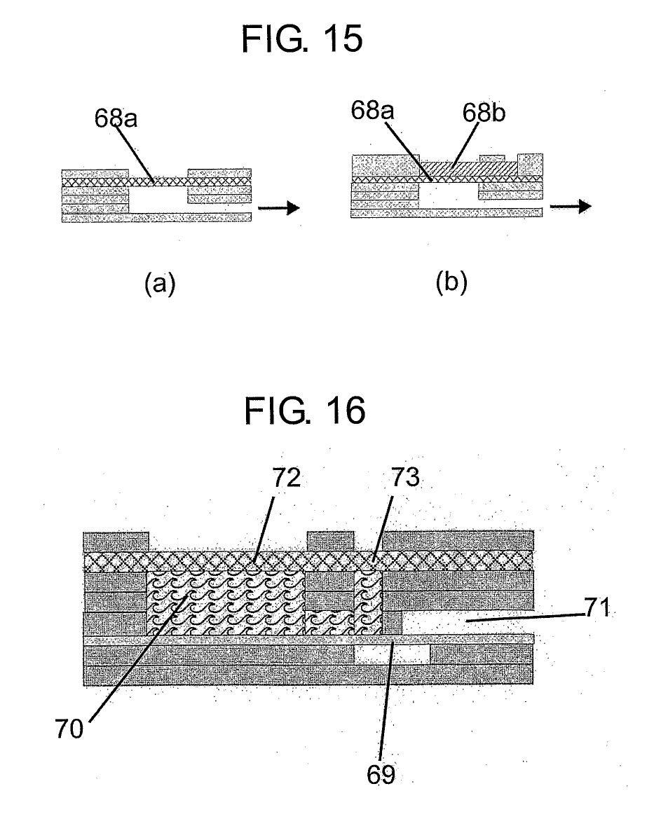

FIGS. 15(a)-15(b) illustrate semi-permeable membranes used as inlet filters and barriers to sample introduction until pressure is applied to push the fluid through the membrane.

FIG. 16 illustrates a controlled dose or reservoir scheme where the fluid is introduced and trapped in the chamber until an applied pressure opens the valve and releases the fluid.

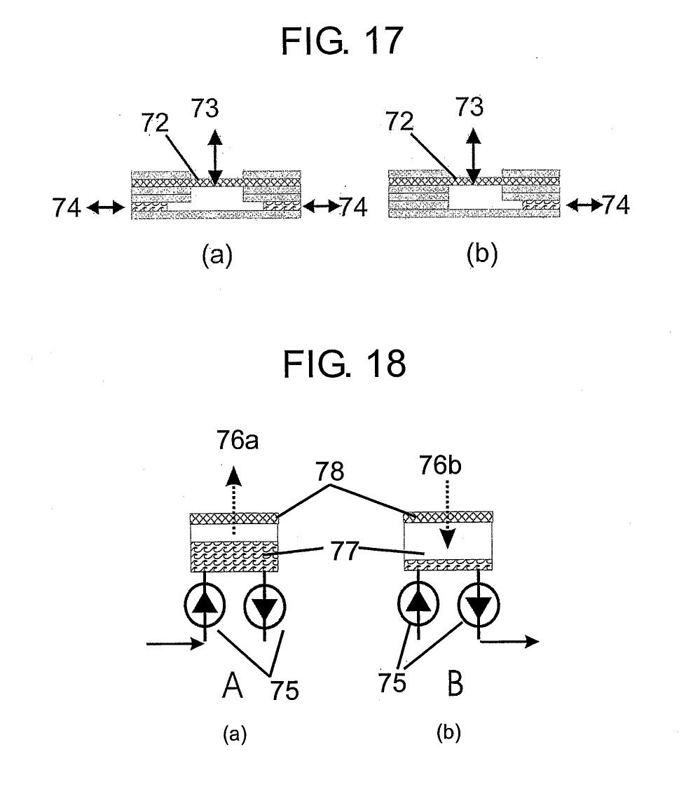

FIGS. 17(a)-17(b) shows a vented channel under applied fluid pressure, positive or negative, operating as a valve or pump.

FIG. 18 illustrates how the vent can be combined with valves to form a pumping system. FIG. 18(a) depicts fluid filling the pumping chamber by a negative pressure gradient across the vent removing the air and drawing the fluid in. FIG. 18(b) depicts the fluid ejected from the pumping chamber by a positive pressure being applied across the vent.

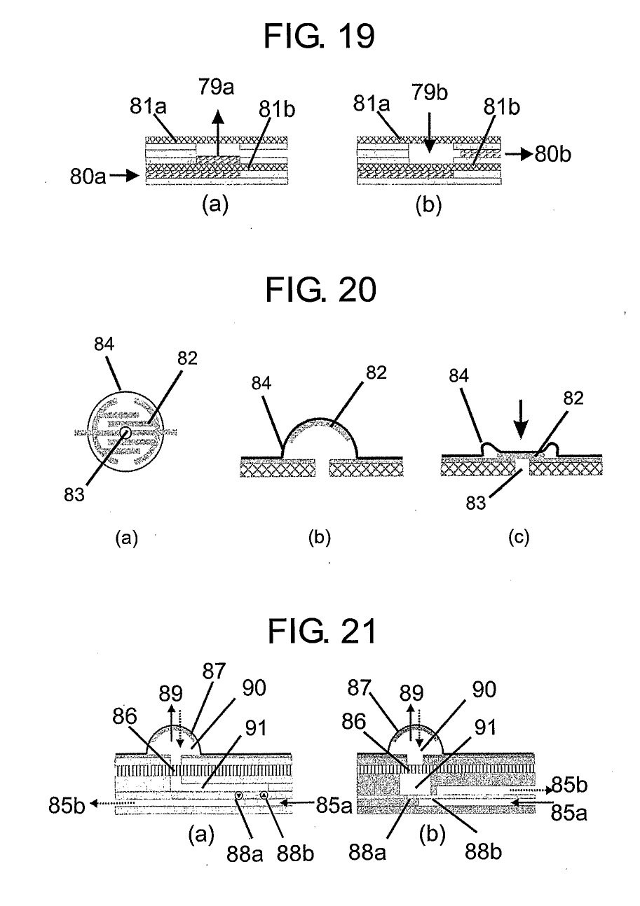

FIGS. 19(a)-19(b) illustrate multiple permeable membranes within a micro-channel network operating as a pump or valve under an applied fluid pressure.

FIG. 20 depicts a button type actuator incorporating electrode pads that are activated during actuator operation. FIG. 20(a) illustrates a plan view of the electrodes inside an actuation area which also comprises a vent hole in the center to allow pressure transfer to another layer within the device to activate another actuation component FIGS. 20(b) and 20(c) are side view cross sections of the electrode structure before and during actuation respectively.

FIGS. 21(a)-21(b) illustrate a cross section of a button style actuator incorporating the electrode and button style interface shown in FIG. 20, with the vent hole connected via a semi-permeable membrane to a pumping chamber using valved inlet and outlets.

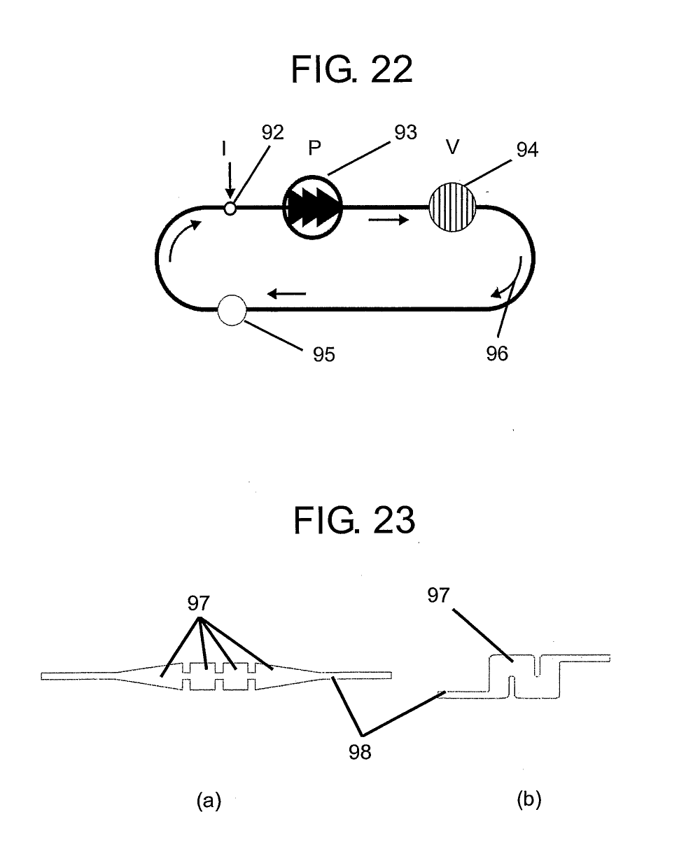

FIG. 22 shows a representation of a recirculating fluidic network.

FIGS. 23(a)-23(b) show two representations of various methods to allow pressure gradient relief to prevent bubble formation. In particular, these figures depict expanded fluidic channels.

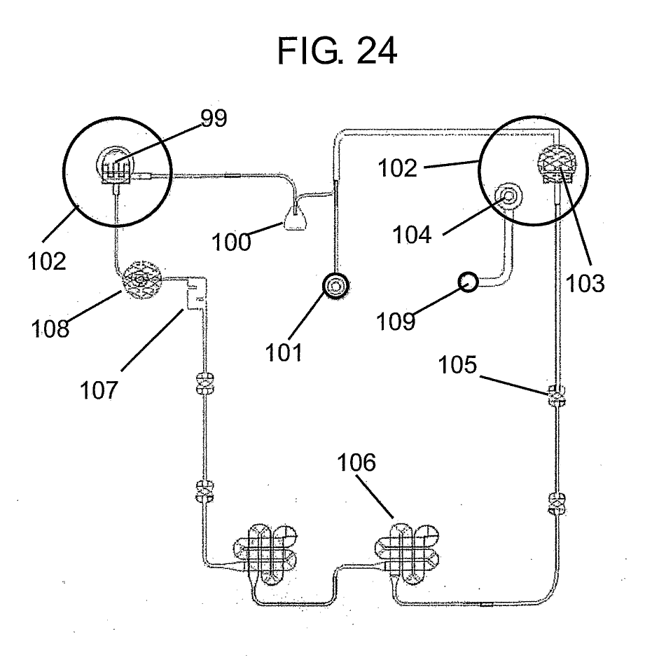

FIG. 24 shows a top view of a multilayer recirculating fluidic network. The recirculating network is connected from the inlet directly to a pump followed by a one way valve, sample introduction port, deformable actuation area containing a vent and one way valve, split flow mixers, detection chambers, pressure relief structures, and then connected back to the input stage.

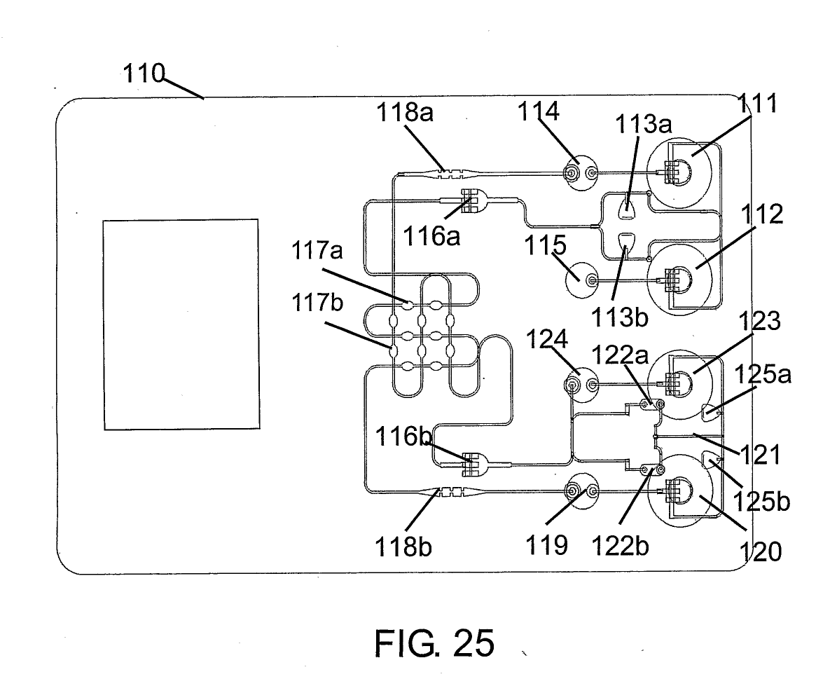

FIG. 25 illustrates the top view composite image of a multilayer device containing two controlled dosing fluidic networks with pumps, valves, debubblers, detection wells, and pressure relief structures

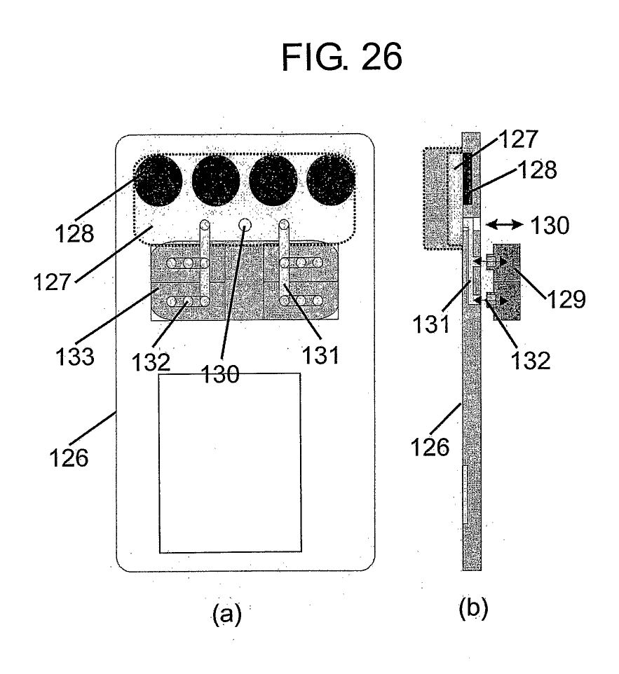

FIGS. 26(a) and (b) illustrate plan and side views, respectively, of a card with pneumatic pumping and valving zones connected to external instrumentation.

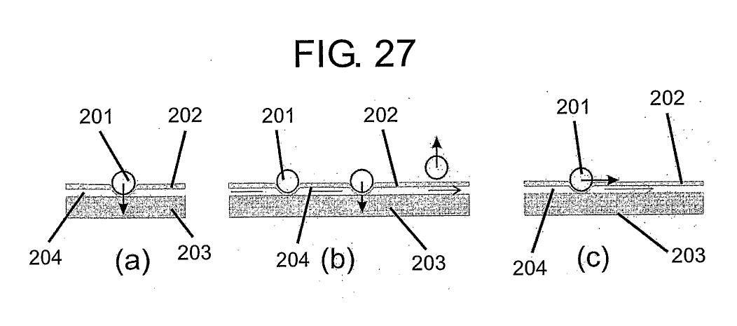

FIGS. 27(a)-27(c) show a transverse cross section of a micro channel with at least one flexible wall, in this case the top layer. FIG. 27(a) illustrates deflection of the deformable material into the channel by a bearing which effectively blocks the channel and produces a closed valve state. FIG. 27(b) demonstrates that three or more inline valves can alternate their on/off state to produce a pumping motion. In simple terms, when a valve closes, the fluid it displaces is moved, alternatively when a valve opens fluid moves to fill the exposed volume. If a valve near the opening or closing valve is closed then the fluid is restricted in movement to and from that direction, whereas if a valve is open then the fluid will flow to or from the unrestricted direction. FIG. 27(c) shows a pumping strategy in which a traveling wave is produced along the channel by moving a partially or fully closed valve along the channel's axis pushing the fluid before it Traveling waves according to the present invention may be produced by any suitable means. For example, sliding or rolling a bearing actuator across a deformable material defining one side of a channel, or similarly by rolling a circular actuator along a channel (thus pushing the fluid wave ahead of the moving actuator in each case).

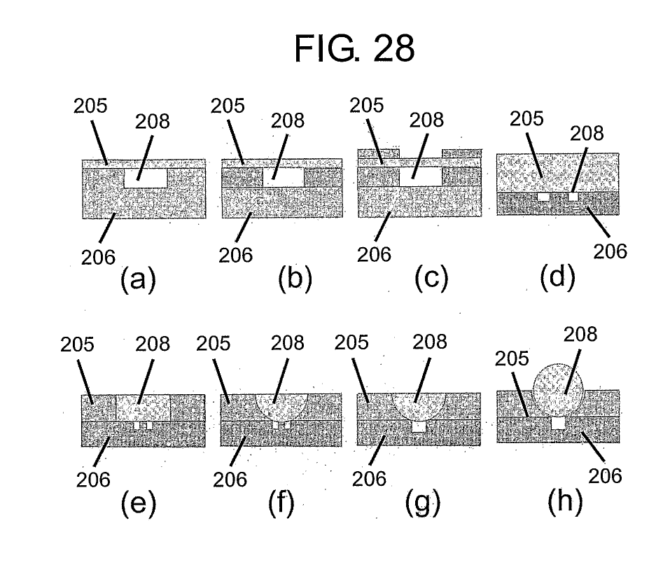

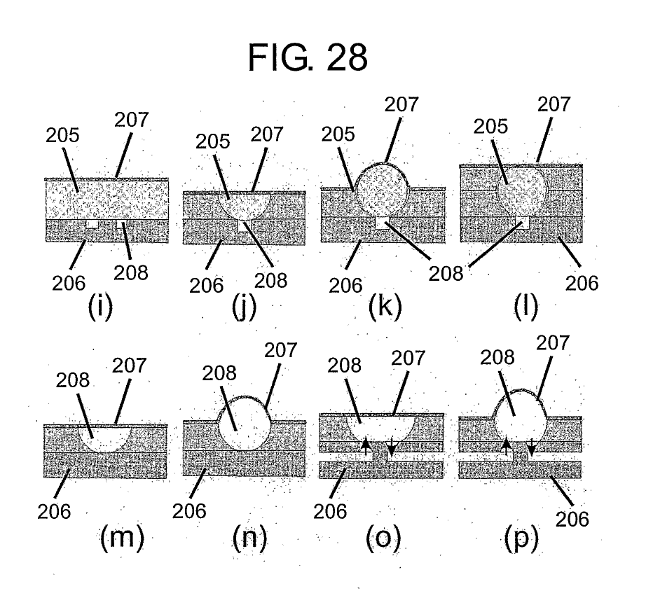

FIG. 28 depicts examples of valve configurations. FIGS. 28(a)-(c) show channels with a single flexible wall that is thinner than the depth of the channel. The channel structures may be etched into a substrate, as in FIG. 28(a), composed of multiple layers, as shown with a 2 layer structure in FIG. 28(b), and may contain other layers on top of the flexible layer, as shown in FIG. 28(c) where a covering layer contains a recess above the flexible layer covered channel. The deformable material may also be thicker than the depth of the channel, as depicted in FIGS. 28(d) to 28(l), and may cover more than one channel. Pressure applied to the deformable material adjacent to the channels can cause the deformable material to deform into the channels, effectively blocking the channels and causing a valving action. The deformable material may also be restricted in other directions by location within other structures. FIGS. 28(e) to 28(g) show the deformable material located within recesses. In a similar manner FIG. 28(h) shows a deformable material in the form of a tubular cross section sitting within a structure above a micro channel. FIGS. 28(i) to 28(l) depict examples where the layer above the deformable material is a single protective covering layer. Whereas FIGS. 28(m) to 28(p) depict cover layers that are used as the deformable material and may be formed or shaped themselves to facilitate deformation in a particular manner, as with a button style interface.

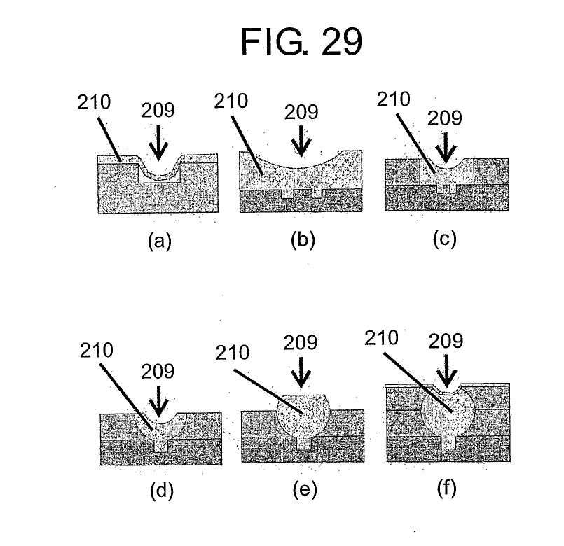

FIG. 29 depicts examples of some of the previously mentioned valves under applied force adjacent to the channel recesses. FIG. 29(a) depicts a thin membrane deflected into a micro channel by a force that is applied to the confines of the recess. FIG. 29(b) shows a thick flexible layer deforming under a much broader application force than the microchannels, the deformable material is deformed into the microstructures. FIGS. 29(c) to 29(e) show variations of a deformable material confined by structures that limit the expansion of the deformable material under the applied force.

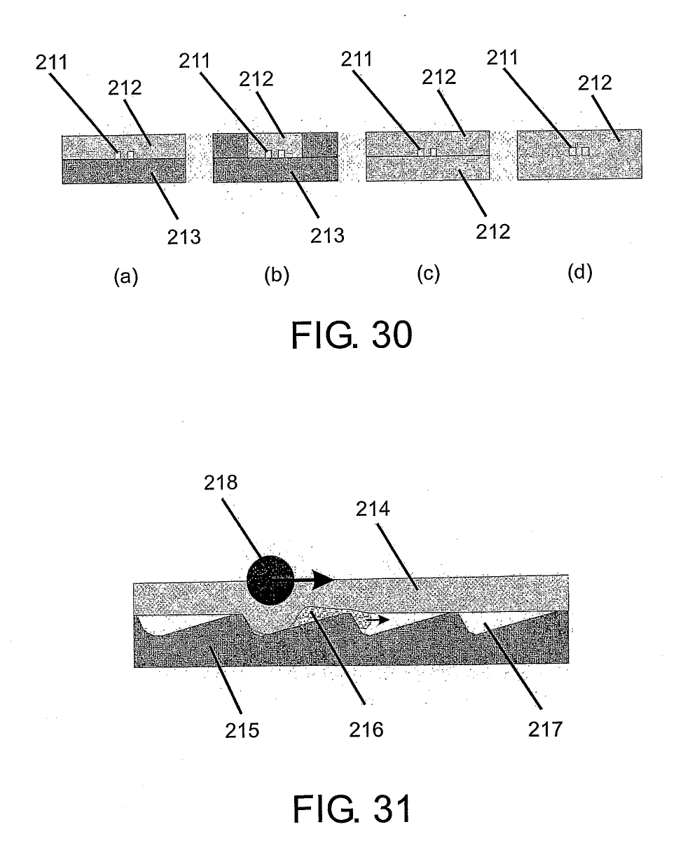

FIG. 30 depicts channels formed within the elastomeric material. FIGS. 30(a), (b) and (c) show configurations with three sides of the channel walls formed from an elastomeric layer, with the channels sealed by an adjoining layer. FIG. 30(d) shows the channels formed entirely within an elastomeric substrate.

FIG. 31 depicts a channel with restrictions placed along the channel length to reduce backflow.

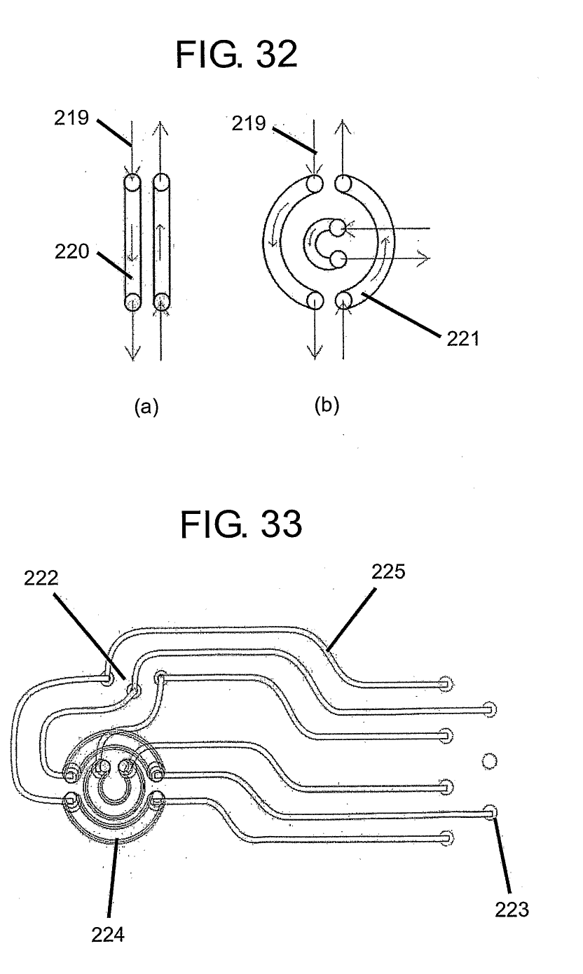

FIG. 32 shows schematic representations of linear and radial pumping channels. The tubes in FIG. 32(a) are straight, or linear, channels with arrows representing the direction of a moving valve or traveling wave pump. Other geometries are possible and an alternative configuration is shown in FIG. 32(b) in which the moving valve or traveling wave follows a radial direction. The ends of the tubes join to other channels or structures to enable fluid flow.

FIG. 33 depicts the top view of a multilayer device using the radial pump configuration connected to microfluidic channels leading to 3-valve locations and inlet/outlet ports.

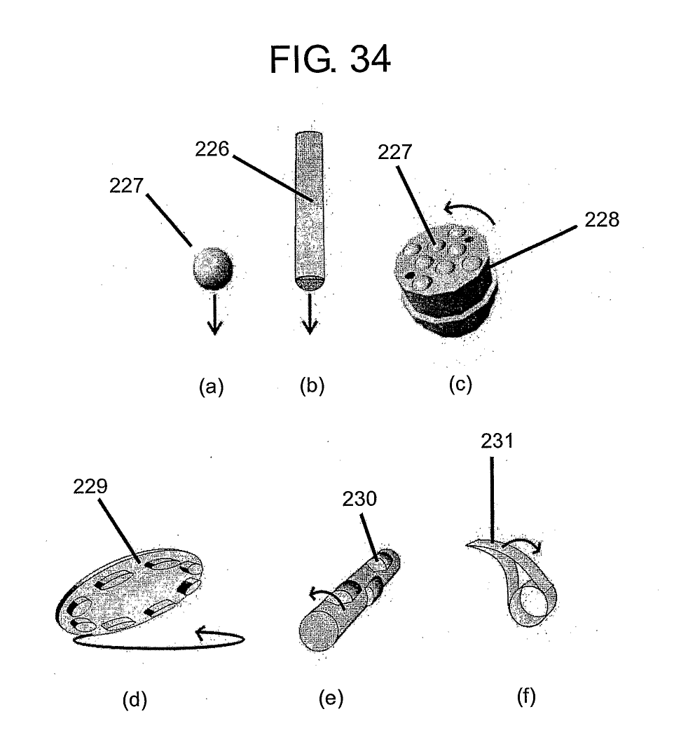

FIG. 34 illustrates examples of driving mechanisms for deforming the materials by mechanical means and thereby producing fluid flow by traveling wave. The actuating structures may be rigid, or deformable to allow the actuator surface to conform to the microstructured valve elements. They may be applied in a perpendicular direction to the valve surface, or moved parallel along the surface. The examples shown are: a spherical object (FIG. 34(a)); a rod (FIG. 34(b)); a rotating housing constraining several spheres that are free to rotate (FIG. 34(c)); raised structures on a rotating platform that is arranged to only contact one surface by wobbling action (FIG. 34(d)); a rotating cam (FIG. 34(e)); and a rotating wiper that applies pressure perpendicular and parallel to the surface (FIG. 34(f)).

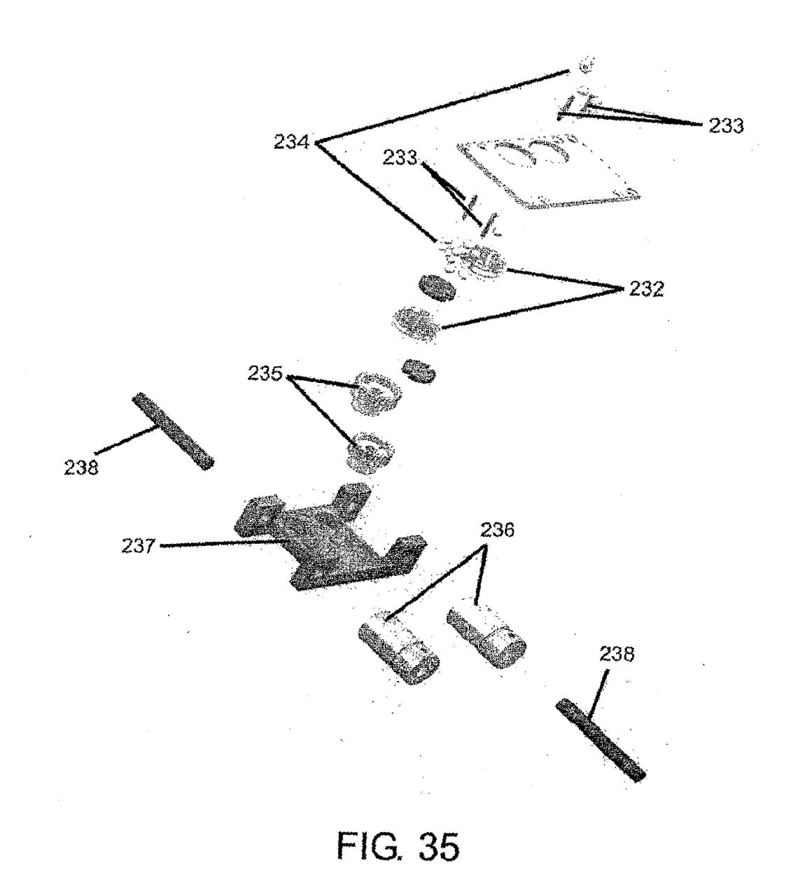

FIG. 35 depicts an exploded view of a radial bearing pump with two actuator heads used to deform the elastomeric layer of the device in FIG. 33.

### Optical Measurement Devices and Methods

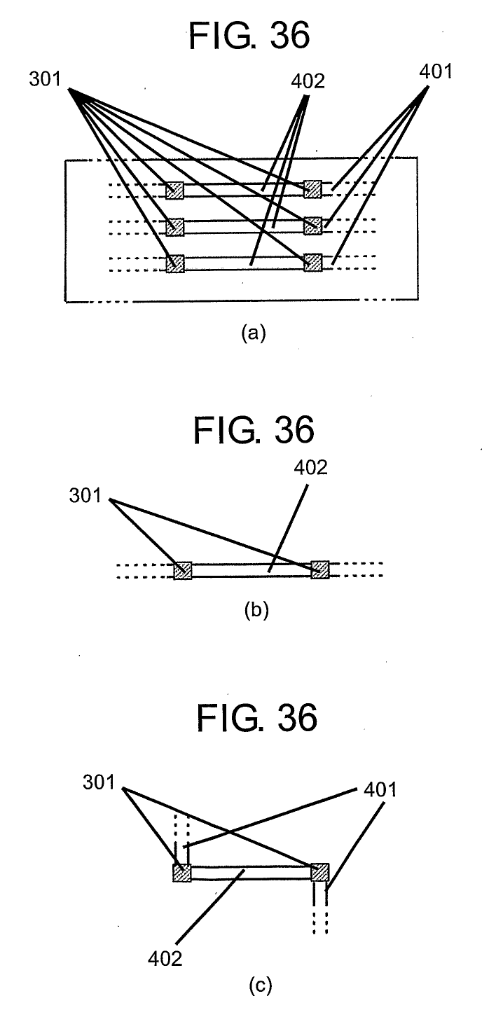

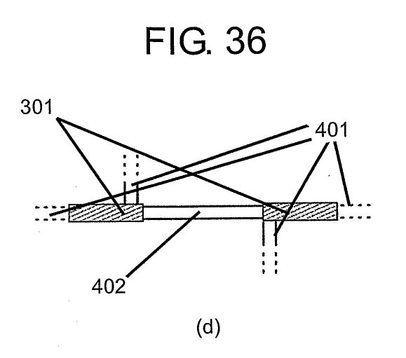

FIGS. 36(a)-36(d) show configurations of microfluidic channels in planar view with transmissive windows separated to allow electromagnetic energy to travel longitudinally along a fluidic channel. FIG. 36(a) represents a plan view of three channels showing the location of transmissive windows placed at suitable distances along a fluidic channel to allow electromagnetic energy to ingress or egress the fluidic channels. In this particular embodiment the electromagnetic energy is in the form of light. FIG. 36(b) shows a single fluidic channel with suitably placed similar transmissive windows. FIG. 36(c) shows a single fluidic channel with suitably placed similar transmissive windows where the direction fluid flow changes in close proximity to the windows. FIG. 36(d) shows a single fluidic channel with suitably placed similar transmissive windows where the fluid flow entering or leaving the channel arrives or leaves by multiple pathways.

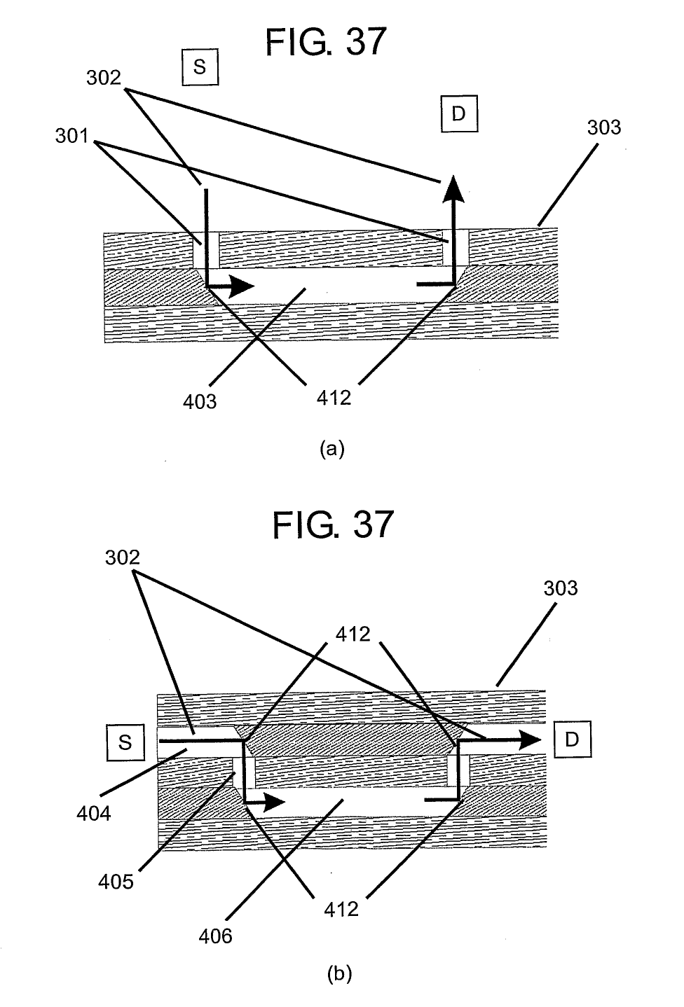

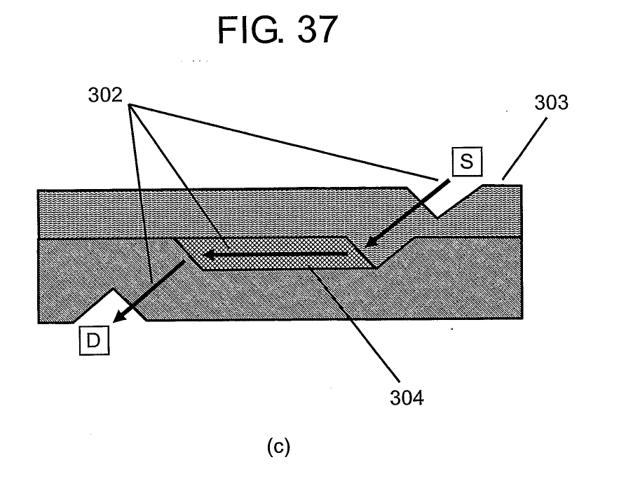

FIG. 37(a) shows the cross sectional view of a three layer device with the optical windows exiting immediately between the channel and substrate surface. FIG. 37(b) illustrates the cross sectional view of a multilayer device having an integrated light path between the fluidic channel and devices surface. FIG. 37(c) illustrates the cross sectional view of a multilayer device incorporating prismatic structures labeled (04) for guiding light longitudinally along a channel.

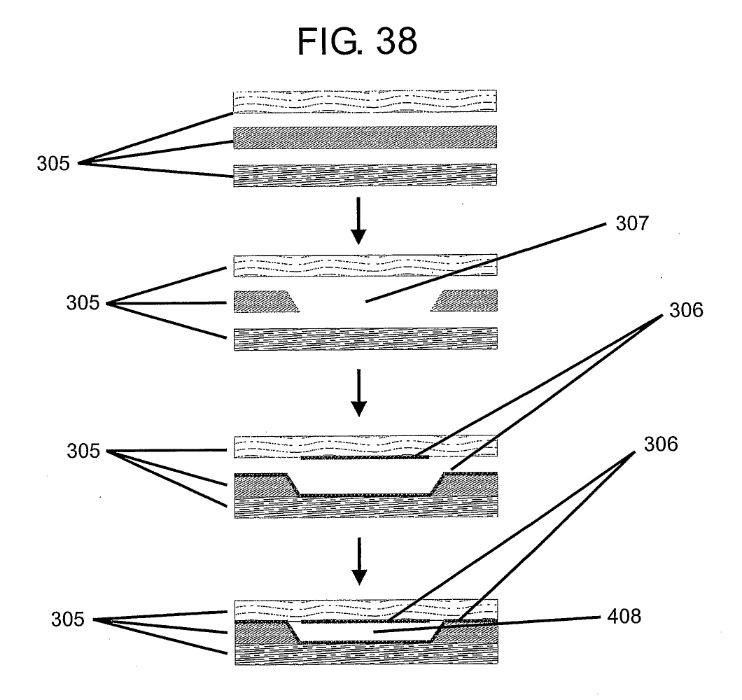

FIG. 38 demonstrates a step by step, 3 layer device fabrication procedure incorporating a reflective coating.

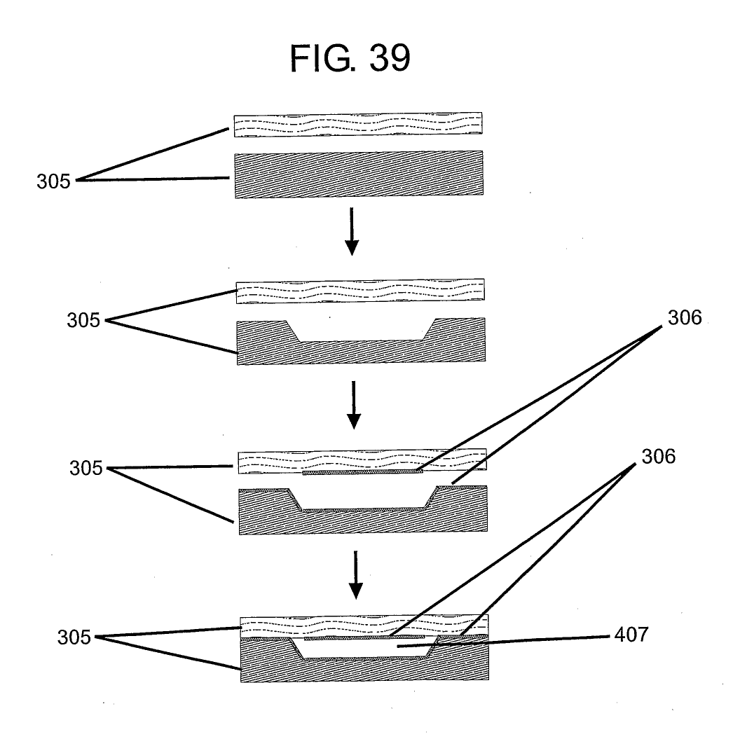

FIG. 39 demonstrates a 2 layer device fabrication procedure incorporating a reflective coating.

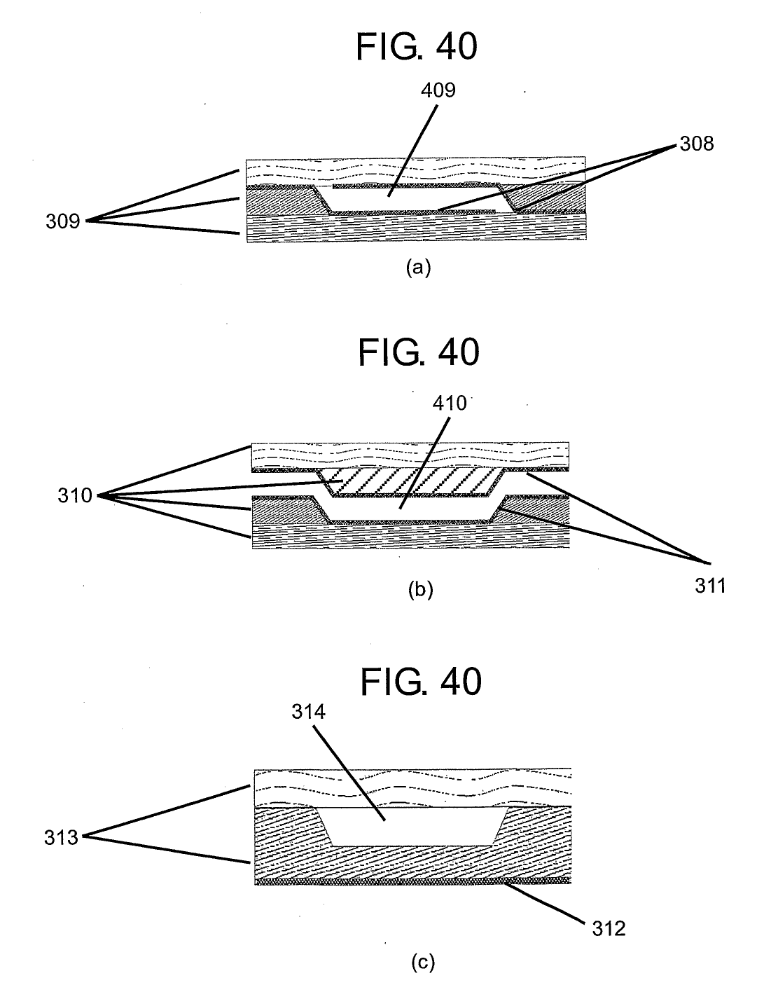

FIG. 40(a)-(c) show various 2 and 3 layer device configurations using reflective layers.

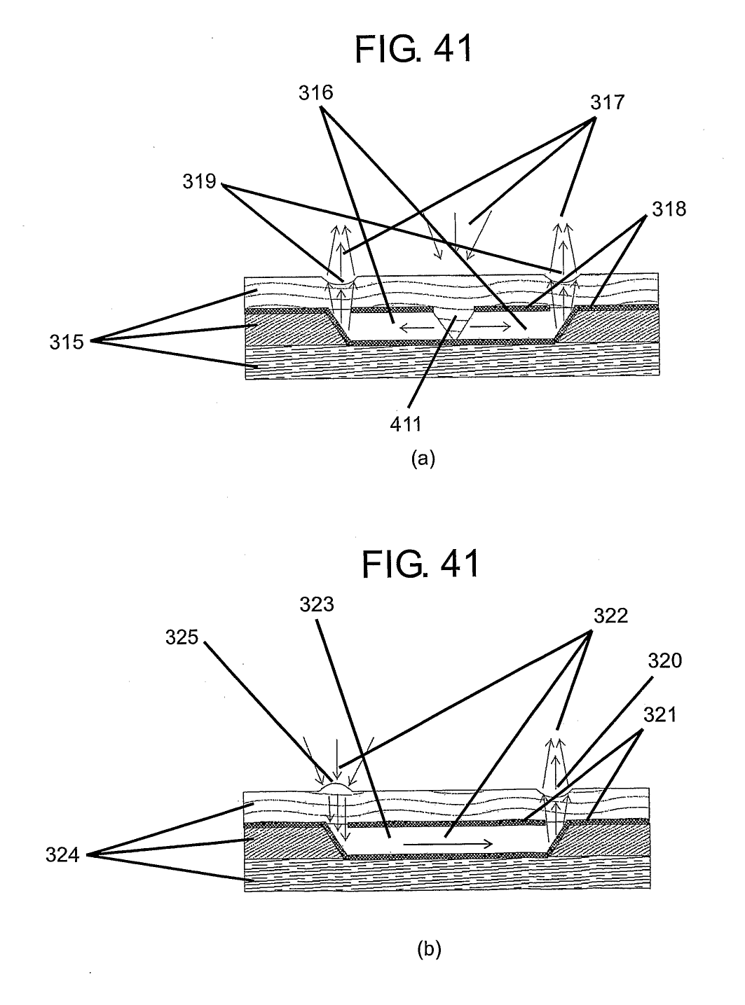

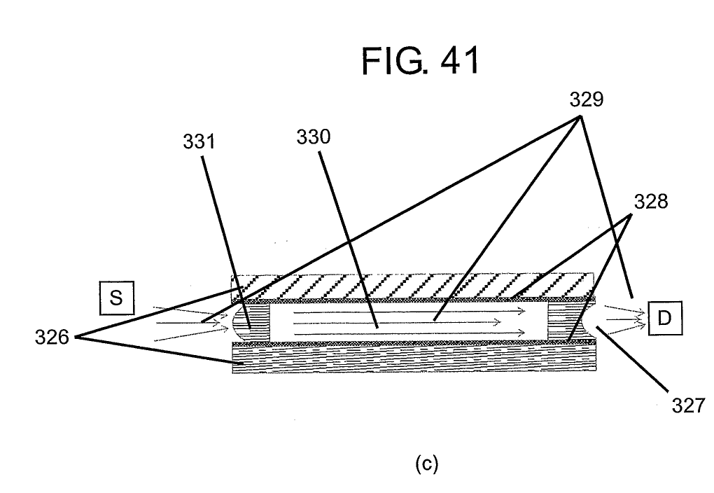

FIGS. 41(a)-(c) provide examples of lenses incorporated into a fluidic device.

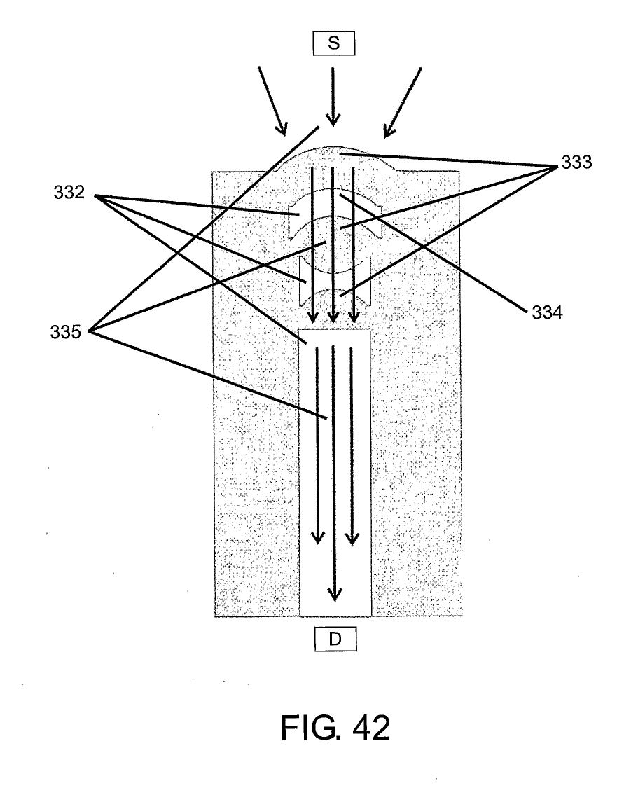

FIG. 42 provides an example of an integrated multi lens system.

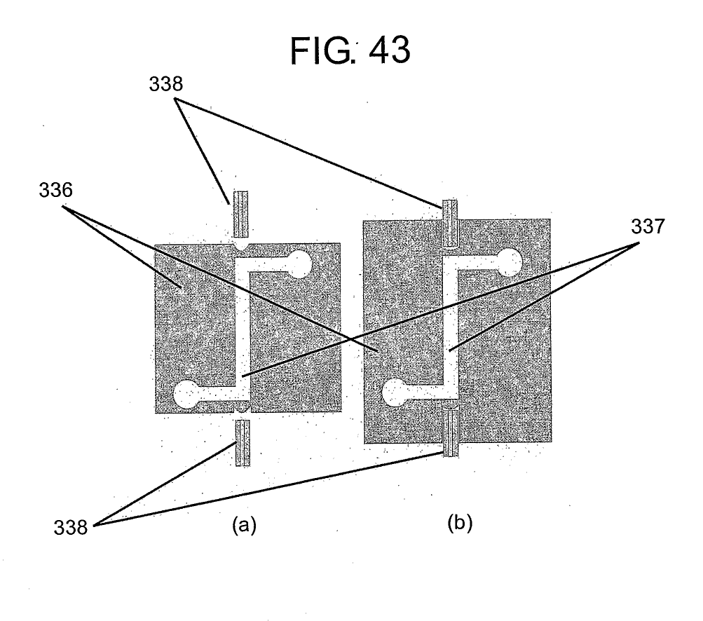

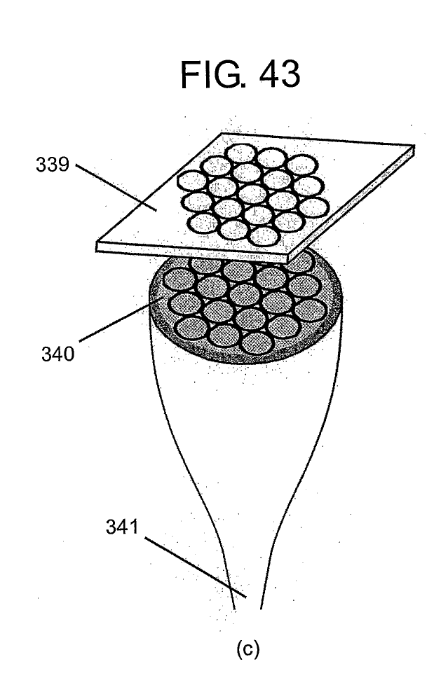

FIGS. 43(a)-43(b) illustrate integration of optical fibers into the device. FIG. 43(c) illustrates a fiber optic bundle located proximally to a microfluidic device.

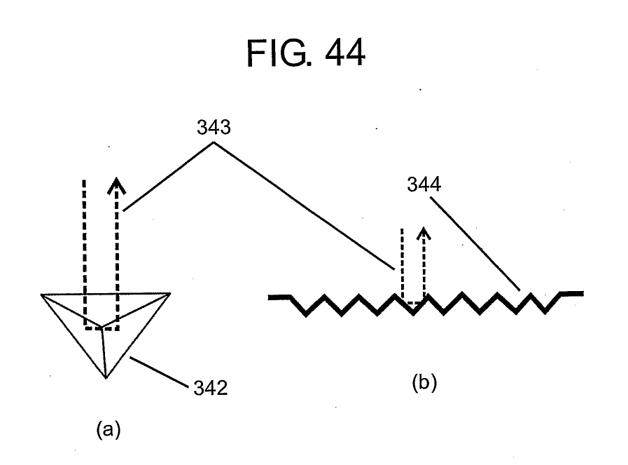

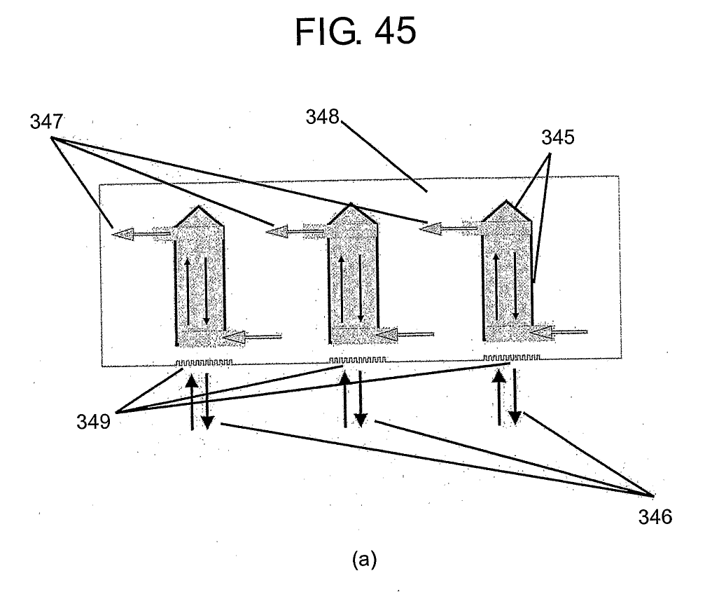

FIGS. 44(a) and 44(b) show diagrams of corner cube reflectors.

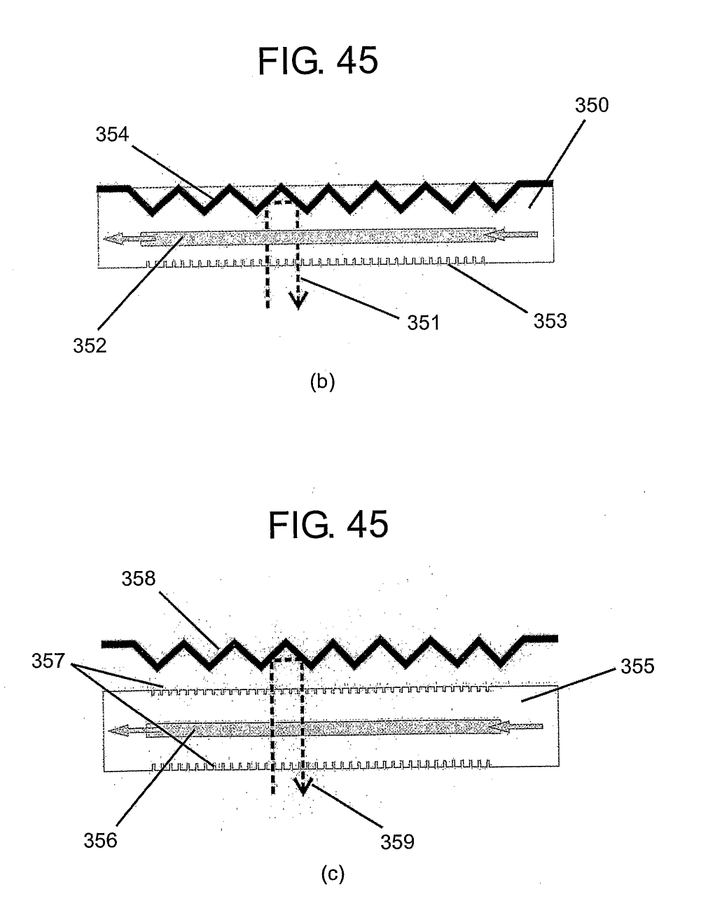

FIGS. 45(a), (b) and (c) show corner cube reflectors used in or with microfluidic devices.

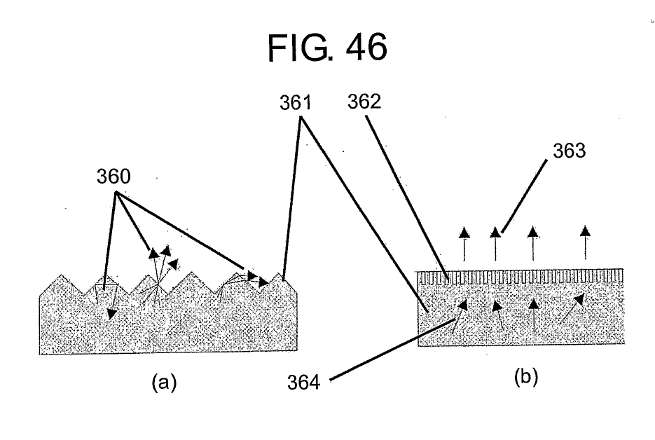

FIGS. 46(a) and (b) show diagrams of prismatic structures used to help collimate and guide light.

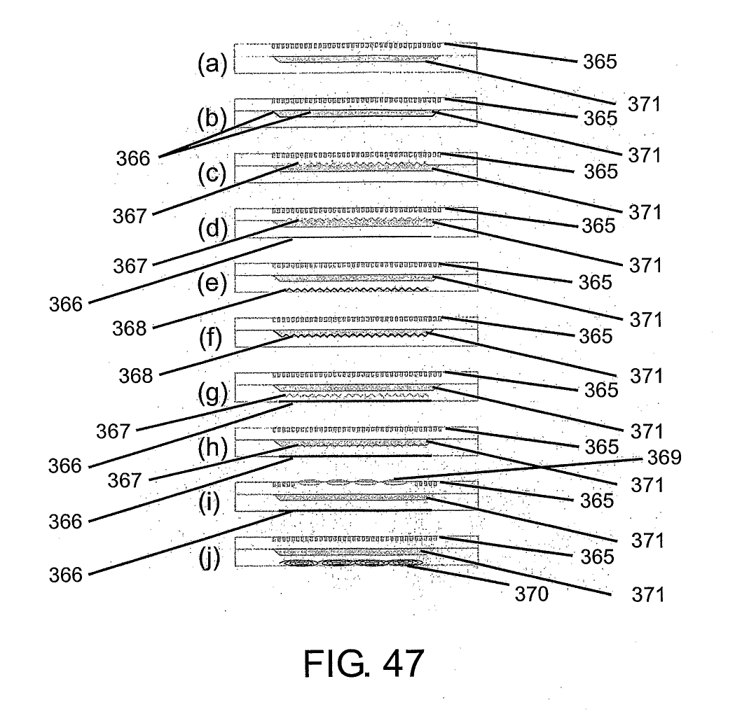

FIGS. 47(a) to (j) show examples of flow cells with prismatic and reflective structures for improved signal response and imaging.

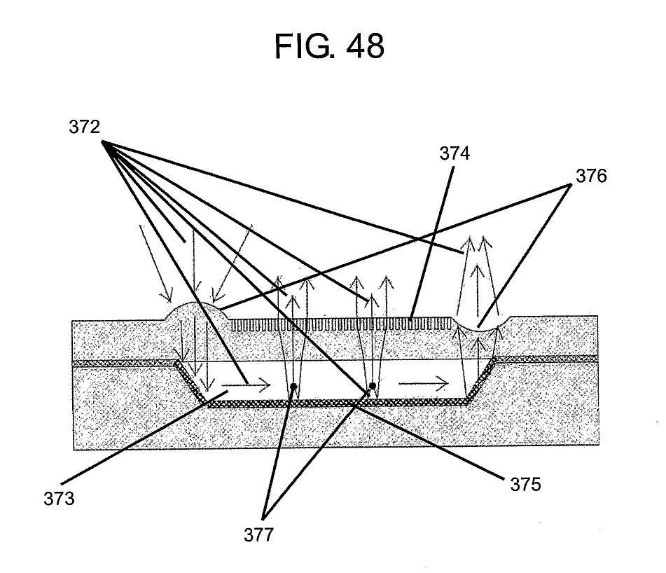

FIG. 48 illustrates an example flow cell with longitudinal and transverse detection.

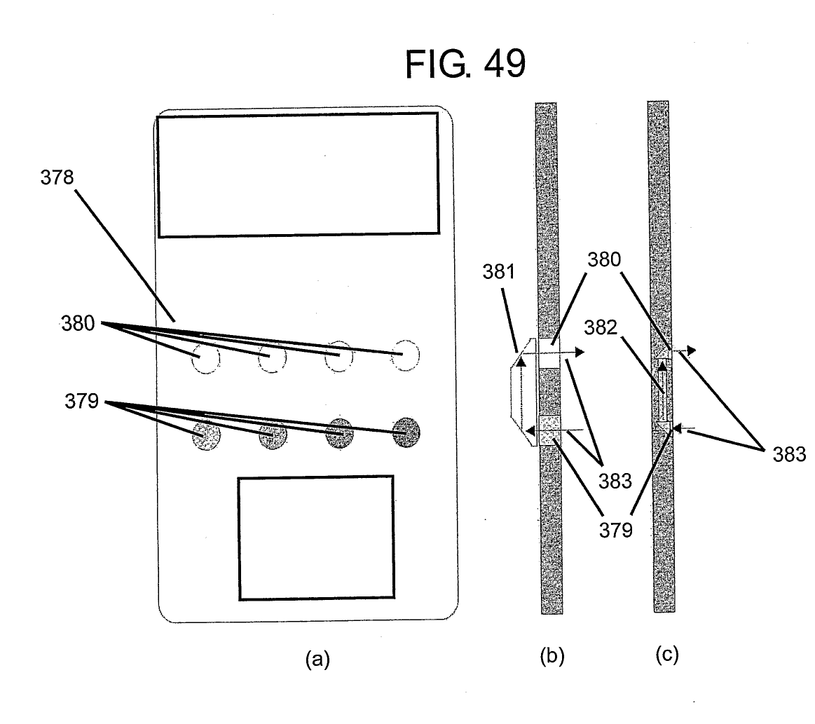

FIGS. 49(a)-49(c) illustrate detector and source zones located proximally on a device.

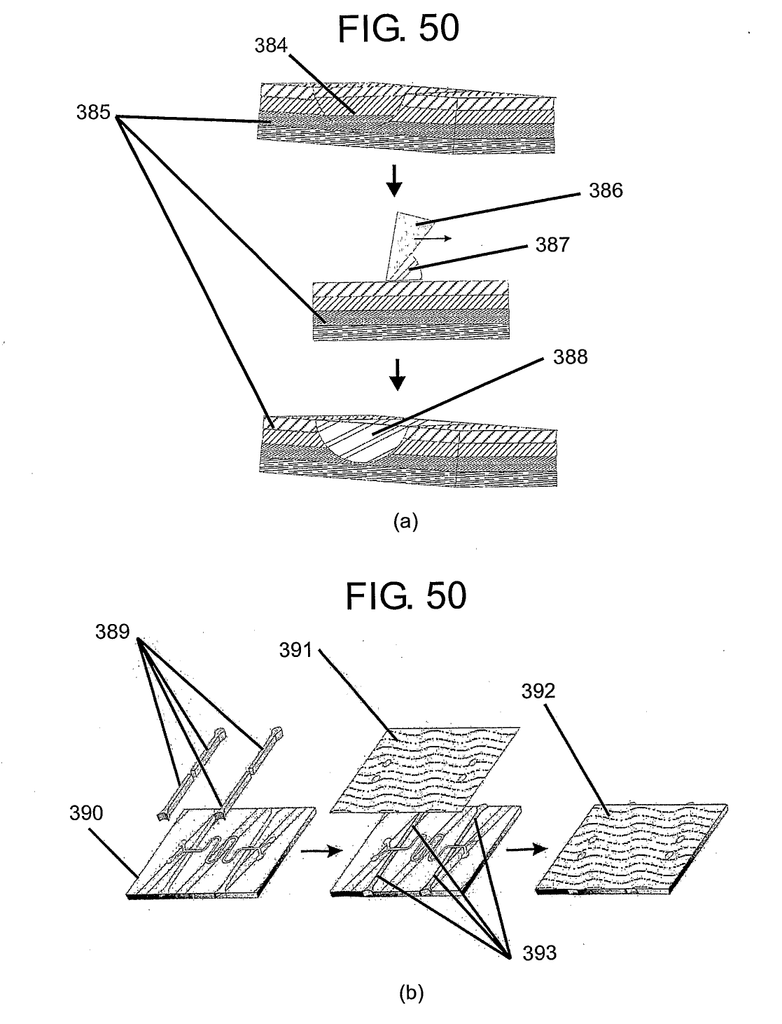

FIGS. 50(a)-50(b) illustrate wave guides which can be made for example by injecting and then curing an optically transparent material, or placing an already formed light pipe into vacant structures.

### Methods of Instrument Configuration

FIG. 51 is a schematic representation of a prior art upgrade path. An upgrade package is supplied to the user, typically in the form of an executable file that installs a setup wizard that either automatically or manually guides the user through the installation procedure of adding the new programming code into the instrument program.

FIG. 52 is a schematic representation of the prior art operation of an instrument with a removable insert. The instrument contains then entire program with all necessary subroutines for any required operations. The insert contains a serial number or product code that allows the instrument to unlock parts of its own program or provides a ‘go to’ type command to allow execution of a particular segment or subroutine of code held on the instrument.

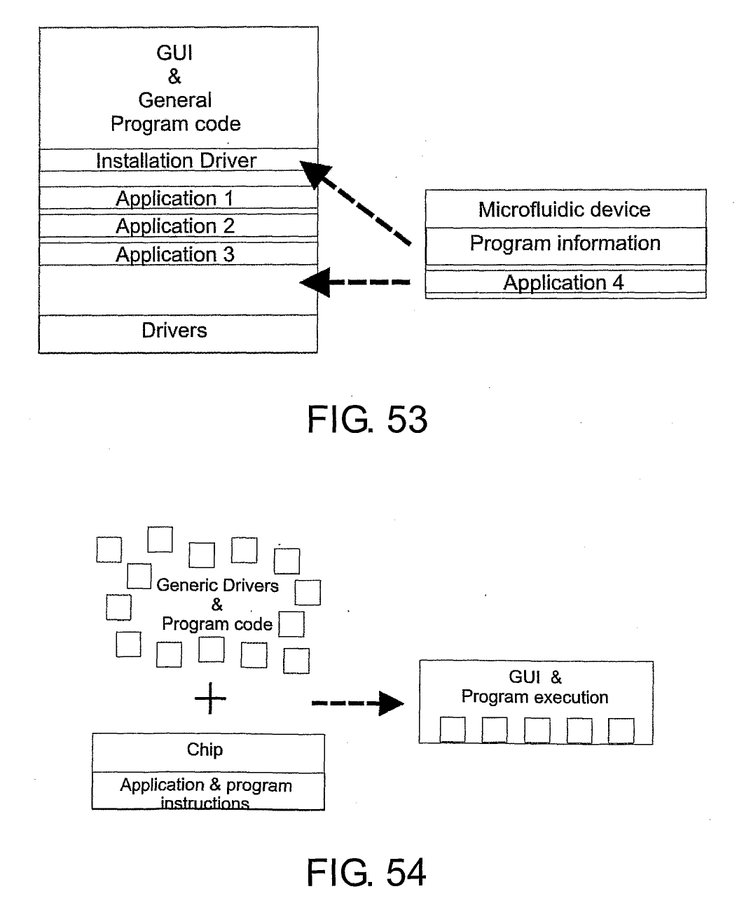

FIG. 53 is a schematic representation of the invention where the insert contains part or all of the upgrade information.

FIG. 54 is a schematic illustration of distributed architecture according to the present invention.

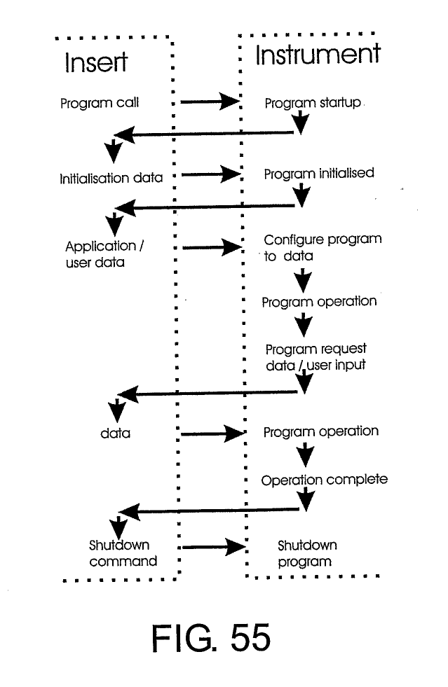

FIG. 55 is a schematic representation of one embodiment of the pathway of the invention in which the instrument contains generic routines and specific program subroutines, but not the operational code required to run the application specific programs required to operate the inserts. The inserts contain the instructions that call the instrument subroutines to operate the instrument for the targeted application.

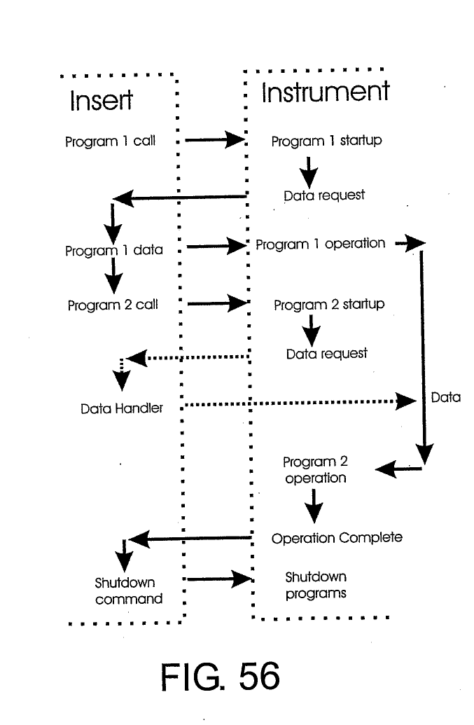

FIG. 56 is a schematic illustration of the pathway according to another embodiment of the invention.

### DETAILED DESCRIPTION OF THE INVENTION

### Articles and Methods for Fluid Manipulation

Various embodiments of the present invention comprise a controller to control fluid flow in the device and a variety of fluid-handling structures containing one or more moveable components, semi-permeable membranes, electrodes, sensors or combinations thereof.

A controller according to the present invention may take any suitable form and preferably comprises an actuator to activate components associated with fluid flow within the device.

The fluid-handling or actuator components may be made from any suitable materials. For example, they may be made from a single shaped substrate or multiple substrates. The fluid-handling structure may be formed in any suitable way, for example it may be formed into the bulk of a substrate or formed from several layers of substrate.

The actuator may be external to the device or part of the fluid-handling device or formed from separate elements that are external to and part of the fluid-handling device.

Actuation may be performed by any suitable means, for example it may be performed manually directly by the user or manually or automatically and indirectly with the aid of an instrument.

According to one embodiment the actuator is pneumatic pressure supplied by interface with an external instrument.

According to other preferred embodiments described, an external mechanical actuator is used to apply pressure to a deformable structure on the device, which deforms and applies pneumatic or hydraulic pressure within the device, or manual actuation by the operator's finger is used. Therefore, according to these preferred embodiments, the deformable substrate(s) may be an integral part of the fluid handling structure, whereas the actuation mechanism is separate. Mechanical actuators may be of any suitable form, for example, they may include bearings, pins, pistons, wobble boards, cams, and wipers. Other desirable embodiments may include use of energy applied in various ways, for example, by instruments or devices containing light, electrostatic, electrical, resistive, piezo-electric, electromagnetic, pneumatic, hydraulic, linear and magnetic force actuators.

The actuator area may cover an entire surface or only a part thereof. FIG. 1 is a schematic representation of an actuation area (03) containing an actuation component (01) with intersecting channel (02).

The actuator area may be on the outer surface of the fluid-handling component or within the fluid-handling device.

According to one embodiment, the actuation area or part thereof may be a moveable component that (for example) changes shape under applied pressure. The moveable material may be an elastomer or any other suitable moveable material which changes shape under applied pressure.

In another embodiment, the actuation area contains a bi-stable or astable material such as a polymer or composite material that can change shape from a predetermined geometry to another predetermined geometry, and may then change back or be encouraged to return to the original state and position once a stimulus (such as an actuator force) has been removed or reversed. Examples of such an arrangement include button type actuators which may be for example manually, thermally, electrically or mechanically operated, that have been suitably formed to allow movement under the actuator force.

Moveable components may be deformed directly into a fluid-handling structure, or indirectly act upon part of a fluid-handling component, to cause or prevent a change in pressure or shape within the fluid-handling component.

The actuation area may be larger than the actuation components.

Actuation component operations include but are not limited to, flow control, pumping, valving, diffusing, droplet delivery, mixing, separating, switching, dosing, injection, sensing, catalyzing, hydrating, dehydrating, and other fluid handling operations that are activated or prevented from activation upon an actuator force. For illustration purposes, FIG. 2 shows schematic representations of some of these components. FIG. 2(a) represents an injection pump (04), FIG. 2(b) a pump (05), FIG. 2(c) an On/Off or variable valve, and FIG. 2(d) a one-way valve.

More than one actuation components may be operated from the same actuator. Examples are shown in FIGS. 3-7. Such an arrangement simplifies device operation, and thereby instrumentation requirements for fluid handling components by reducing actuator control and space requirements. By combining multiple actuated components operated by the same mechanism operating efficiencies can also be improved for various functions, such as pumping, valving, mixing, injection, controlled dosing, switching and other fluid-handling operations.

Schematic representations of where more than one actuation component, of the same type, is operated from one actuation area are shown in FIGS. 3. FIG. 3(a) illustrates three inline pumps (09) connected to three separate channels (10) actuated from the same mechanism (08). FIG. 3(b) illustrates three injection pumps (11) connected to three separate channels (10) operated in the same actuation area (08). FIG. 3(c) illustrates three on/off or variable valves (12) connected to three separate channels (10) operated in the same actuation area (08). By combining these actuation components from independent channels on the same actuation area; productivity, size, cost and simplicity improvements are made by requiring only a single actuation mechanism to operate all components in the same actuation area; and applications requiring critical timing of actuation components can be simply and accurately implemented. FIG. 3(d) shows an example of an intersection of channels (10) where four of the channels have On/Off or variable valves (12) operated in the same actuation area (08), enabling controlled dosing to or from all the valved channels from a single operation. FIG. 3(e) shows an example of two inline pumps (09,13) that operate on opposing strokes (applied pressure) of the same actuation mechanism from the same actuation area (08), thereby improving pumping efficiency when the channels (10) from each pump are connected in parallel by pumping on both positive and negative cycles of the actuation mechanism.

Schematic representations of where more than one actuation component, of more than one type, is operated from one actuation area are shown in FIGS. 4. FIG. 4(a) illustrates an in-line pump (17) and two On/Off or variable valves (16) on independent channels (15) operated from the same actuation area (14). FIG. 4(b) illustrates an in-line pump (17) connected to On/Off or variable valves (16) on separate channels (15) operated from the same actuation area (14). If the variable valves are set to different flow rates then the pumped fluid can be repeatedly proportioned to either valve outlet. FIG. 4(c) illustrates an injection pump (18) connected to four channels (15) with On/Off or variable valves (16) operated from the same actuation area (14), allowing the injected fluid to be proportioned to each channel. FIG. 4(d) shows a schematic representation of an inline pump (17) with in four intersecting channels (15) containing On/Off or variable valves (16) all operated from the same actuation area (14). This configuration provides flow control of the pumped fluid into or out of the valved channels.

The pumping schematics shown in FIG. 5 illustrates three types of pumps that proportion fluid from a common channel or reservoir. FIG. 5(a) shows an in-line pump (21) connecting two On/Off or variable valves (22) on separate channels (20) operated from the same actuation area (19), splitting the pumped media into the two channels according to the valve configurations. FIG. 5(b) shows an injection pump (23) connecting two On/Off or variable valves (22) on separate channels (20) operated from the same actuation area (19), splitting the injected media into the two channels according to the valve configurations. FIG. 5(c) shows two sets of three On/Off or variable valves (22) on separate channels (20) operated from the same actuation area (19). By configuring each valve to actuate in sequence a peristaltic type pumping motion can be achieved by a single actuation in either channel.

According to the invention, actuation components may operate differently depending on their composition and geometry even when activated by the same actuator. Examples of this include: pumps operating at different flow rates due to their geometry, and valves, where some are turned to their OFF state while others are turned ON during actuation, or variable valves that are set to restrict the flow to different levels, or components that are activated at different times by the same actuator. Examples of arrangements which provide for controlled dosing are shown in FIGS. 5. Such valves may be set in a variety of ways to provide for controlled dosing. For example, they may be set to close at different points during the actuation cycle, or set to restrict the flow rate, effectively allowing a controlled volume dosing event to occur.

According to another aspect of the invention actuation components may operate differently depending on their configuration with the same actuator. FIG. 3e illustrates an example of such a configuration where two pumps are connected in parallel operating from the same actuator. The actuation components may operate in unison or in different parts of the actuation cycle, for example one pump propels fluid on the downward stroke of the actuation cycle while the other pump propels fluid on the upwards stroke.

In another embodiment multiple valves can be operated from the same actuator to induce fluid flow by alternating their on/off states to produce a peristaltic motion. A peristaltic type pump configured from three differently activated valves operated by the same actuator is shown in FIG. 5c.

Multiple actuation areas may be combined to perform fluid-handling operations. An example of such an arrangement is illustrated in FIGS. 6 and 7 in which one fluid stream crosses another allowing a predetermined volume transfer between the two streams. In the example of FIG. 6 the streams (23,24) are alternatively activated by the pump-and-valve actuation areas (26,27) causing the injected stream to flow and the non-pumped stream to be valved by the actuation of the pumped stream. This prevents backflow of one fluid into the channel of another except at the point where they cross over (25), thereby providing a controlled dose or plug of fluid that can then be injected into the stream of the other. In the schematic representation of FIG. 7 the fluid stream (30) is pumped by (28), and if the backpressure in channel (32) is higher then the fluid crosses over channel (32) at (31) and out through the valve of (29). Therefore when (29) is activated fluid along channel (32) is pumped, but does not backflow into (30) due to the activation of the valves of (29). Therefore if fluid was introduced from (28) prior to activation of (29), then the plug of fluid at the crossover of the two streams (31) is injected and carried along with the fluid pumped from (29).

FIG. 8(a) illustrates an embodiment of such an actuation area (33) in which the two center channels are connected together by the two circular one-way valves (34) allowing a pumping action to be performed upon actuation, as shown in FIG. 8(b) with the arrows providing fluid flow direction upon alternate actuation cycles, (34a) and (34b) represents upwards and downwards actuation cycles, respectively. Whereas the rectangular actuation components (35), of FIG. 8(a), are on/off valves that allow the deformation of a membrane (36) to block a channel to stop flow during actuation, as shown in FIG. 8(c) with the valve cross sections shown in On (35a) and Off (35b) modes. Another embodiment shown in FIG. 8(d) illustrates the operation of two types of valves operating as a pump. The filling motion (37) causes the membrane (36) to deform upwards allowing the fluid into the pumping chamber, and on the empty cycle (38) the membrane (36) is pushed against the base of the chamber closing the inlet slit and deforming the membrane into a lower channel, allowing the fluid to pass under the restriction before the outlet channel. Another example of a three-way valve is provided in FIG. 8(e) where a deformable layer (40) is used to close off a particular port when pressure is applied from an opposing port (39) that deforms the membrane to cover the port where no force is applied. The membrane may be located to one side of the chamber or channel to close off a particular port by default, which only opens when pressure is applied from the initially closed port.

Another aspect of the present invention may include one or more semi-permeable membranes that can act as vents or check valves to allow for example, air passage but prevent liquid flow under low pressures. Examples include, but are not limited to perforated film or fibrous membranes, that have a bubble point pressure greater than >0 psi. A preferred embodiment uses hydrophobic membranes with pore sizes less than 0.9 μm, preferably less than 0.5 μm and most preferably less than 0.2 μm. Where the pore size is less than 0.2 μm, then preferably the membrane is suitable for biological organism trapping. Semi-permeable membranes may be, used for example, as vents for debubbling the fluid handling structures caused from priming, dead volumes and operations such as pumping, an example of which is depicted in FIG. 9(a) in which an inline pump (43) incorporates a debubbler (41) downstream. The semi-permeable membranes may also be configured as check valves, an example of which is depicted in FIG. 9(b) in which an injection pump (44) has a downstream vent (42) for operation as a check valve. This configuration allows safe storage and handling of fluid in the structure, which is only injected into the system upon actuation. FIG. 10 illustrates the cross section of a channel with a debubbler. Fluid (47) with bubbles (45) pass by the semi-permeable membrane (46) where the bubbles (45) are preferentially removed through the membrane due to a lower pressure differential (48) across the membrane than would be required for the air bubbles to continue down the channel.

In another embodiment a vent (50) is placed to degas a structure (49) to ensure full packing of the channel and or chamber (52,53). Packing materials may be of any-suitable type, for example they may be fluid or solid. The example in FIG. 11 depicts a vent (50) placed downstream from a detection chamber (53) for degassing to remove the air that is initially within the structures when the fluid is introduced from the inlet port (51).

In another embodiment the use of surface tension and geometric structures can be used to help guide the liquid past the vent while the gas is removed. FIGS. 12(a) and 12(b) depict plan and cross-section views, respectively, of an example device (55) with a relatively large surface area vent (56) above a microchannel (54) for easing gas venting. The microchannel extends through the floor of the venting chamber (57), surface tension in the channel and in the venting chamber help guide the liquid along the channel while the gas is released into the chamber and then out through the vent (56). In another embodiment FIG. 13 shows an example of a vent structure that uses a regulating valve (60) feature to prevent air passing the vent. Liquid will only pass the regulating valve (60) when a certain pressure is reached within the venting chamber (61). As this regulating pressure is higher than the bubble point of the permeable membrane the gas (59) will preferentially be expelled through the permeable membrane (58) (FIG. 13(a)). When the venting chamber (61) is full of liquid and pressure is applied the deforming membrane (62) will deform allowing the liquid to pass to the outlet (FIG. 13(b)).

In another embodiment the vents can be combined with a deformable structure and a one-way valve, or restriction, for liquid loading or pumping. For example, FIGS. 14(a) and (b) depict the top and side views respectively of a debubbler type vent (63), as per FIG. 13, combined with a one way valve (67) under a deformable structure (66). Here the one way valve (67) is configured to relieve the pressure by allowing air passage through (65) when the deformable structure (66) is compressed and to seal when the deformable structure returns to its original state. Therefore a negative pressure is generated inside the device that sucks fluid in from a channel to fill the chamber (64) with a known volume. Other pumping mechanisms can then be used to push that known volume of fluid past the debubbler inside the device, as per the recirculating network of FIG. 22.

In another embodiment, the vents can be configured to sample introduction filtering and fluid control. FIG. 15(a) depicts a semi-permeable membrane (68a) over an inlet well. Upon an applied pressure difference greater than the membrane's bubble point, the components within the sample small enough to move through the membrane pass through the membrane (68a) layer and into the device. Effectively filtering the sample and delaying sample entry until the pressure is applied. The example of FIG. 15(b) provides two semi-permeable layers placed over the inlet to a fluidic device. The first semi-permeable layer (68b) in contact with a sample is configured as an absorbent medium to initially absorb and contain the sample within a defined location, thereby allowing a controlled dosed volume of the sample into the device when pressure is applied across the filtering semi-permeable layer (68a). In this example the sample wicks through the absorbent material before pressure is applied to bring the sample into the device. Upon a sufficient pressure gradient only the sample in the exposed area immediately above the membrane is moved into the device.

In another embodiment the semi-permeable membranes (72) can be used to effect a controlled volume dispense and storage. FIG. 16 illustrates an example where the reagent, or sample, can be injected through the membrane into the large reservoir chamber depicted (70), which will fill with a known volume. A small vent area (73) is provided to remove air and relieve pressure during filling so that the exit valve is not released. When injection into the device is required pressure is applied to the semi-permeable membrane (72) (with the vent area sealed or equally pressured) pressurizing the fluid chamber, forcing the liquid out through the pressure relief valve (69) into the channel (71). A similar approach is to load the sample by means such as injection through an elastomeric layer into the reservoir chamber (70), therefore a separate vent area (73) is not required as any exposed semi-permeable membranes (72) would perform this venting function.

In another embodiment the fluid can be introduced through a semi-permeable membrane to perform valve or pumping functions. FIGS. 17(a) and (b) show vents (72) placed at the intersection of two channels and at the end of a channel, respectively. The fluid inside the device can be controlled by applying another fluid (73) (e.g., a liquid and gas) that can preferentially flow through the permeable membrane (72). In this example, the applied gas (73) can be used to drive the liquid (74) through the channel network or used to stop the fluid flow. The bubble point pressure (surface tension) prevents the liquid from passing through the membrane. Geometric structures may also be used in combination with the semi-permeable membrane to restrict fluid flow.

In another embodiment the vent (78) can be combined with one-way valves (75) to form a pumping system. An example of such a system is illustrated in FIG. 18. FIG. 18(a) depicts a fluid filling the pumping chamber (77) by a negative pressure (76a) gradient across the vent (78) removing the air and drawing the fluid in. FIG. 18(b) depicts the fluid ejected from the pumping chamber by a positive pressure (76b) gradient being applied across the vent. The air movement can be supplied from an external pneumatic interface or an integrated actuator, such as a button style pump as depicted in FIG. 20.

In another embodiment more than one semi-permeable membranes are used for fluid control within the structured network. FIG. 19 illustrates an example where two semi-permeable membranes 81a, 81b) with different bubble points are used. An applied negative pressure (79a) can be used to draw fluid from the channel (80a) through the semi-permeable membrane (81b), then a reduction in pressure or the use of a secondary semi-permeable membrane (81a) with a higher bubble point than the applied pressure gradient (79a) is used so the liquid is prevented from passing through this layer (81a). A positive pressure (79b) can then be applied (FIG. 19(b)) to force the fluid through the outlet (80b), which may contain a restriction, valve or other flow control features.

In another embodiment electrodes are included in the actuation area to provide electronic switching for sensor operation, circuit operation or detection of actuation events. An example is shown in FIG. 20 depicting a button type actuation area (84) incorporating electrode pads (82) that are activated during actuator operation. In this example a hole in the substrate (83) is provided for pressure relief during actuation of the structure (84), the induced pressure from actuation may then be used within a device below the substrate for actuation purposes.

In another embodiment a button, or other deformable structure is combined with a semi-permeable membrane. This offers advantages for chemical storage, injection, pumping, valving and other fluid manipulation operations by providing a controlled actuation volume. For example, FIG. 21(a) and (b) depict two pumping strategies where the fluid pumping chamber (91) is kept separate from the large actuation volume (90) inside the deformable actuation structure (87). These two geometries can then be tailored to provide the optimum pumping conditions; with the volume inside the deformable structure (90) used to control the pumping pressure, and the fluid pumping volume (91) on the other side of the semi-permeable membrane (86) used to define the pumping volume. Furthermore, the semi-permeable membrane (86) can be used to keep away corrosive or other fluids detrimental to the operation of the deformable actuation structure (87), such as preventing liquid from corroding electrode sensors on the deformable structure. In examples shown in FIG. 21 a downward actuation force (89) deforms the deformable actuation structure (87) reducing the actuation volume (90), pressurizing the pumping chamber, thereby fluid is forced through a one way valve (88) and out through the channel (85b). Upon removal of the actuation force (89) and return of the deformable actuation structure (87) to its original shape the negative pressure draws fluid in through a one way valve (88) into the fluid pump chamber (91).

In an alternative situation the deformable actuation structure (87) may act as an injection pump by containing a fluid in the actuation volume (90) that is kept out of the channels of the device until actuation upon the deformable structure causes the internal pressure to rise above the membranes retention point.

In another embodiment a recirculating fluid system is provided. With the use of a degassing component the outlet can be connected to the inlet and air that is introduced into the system is removed before the fluid passes through to a functional area. In this manner the fluid can be mixed more effectively and pass the functional area multiple times. This has advantages in many applications including sample preparation, such as cross flow filtration, solid phase chemistry, and detection in microfluidic systems. FIG. 22 shows a schematic representation of a recirculating fluidic network with inlet (92), pump (93), debubbler (94), and detection chamber (95). The arrows (96) represent fluid flow direction while pumping.

In other embodiments internal pressure relief structures (97) are used to prevent bubbles from forming in undesired regions. For example FIG. 23 depicts two such structures that can be employed in channels (98) near the exits of recirculating networks to avoid the suction force from the pump separating the fluid chain at the next point of lowest pressure. In some cases this is at or near a detection zone which may be adversely effected by the formation of bubbles. By introducing these extra wide areas (97) the fluid will preferentially separate at this point rather than near the detector areas.

FIG. 24 shows a top view of a multilayer recirculating fluidic network. The recirculating network is connected from the inlet (108) containing an semi-permeable membrane, for filtering and sample loading, directly to a in-line pump (99) in an actuation area (102); followed by a one way valve (100); a sample introduction port, with a one-way valve for backflow restriction (101); a deformable actuation area (102) containing a pressure relief valve and vent (103) for debubbling, and a one-way valve (104) with air return (109), this ensures that positive pressure in the actuation area is released through the air return (109) and negative pressure draws in fluid from the sample inlet (101) for controlled volume sample loading; split flow mixers (105) that segments, inverts, and then recombines the flow for improved diffusion based mixing; detection chambers (106); pressure relief structures (107); and is then connected back to the input stage (108) for recirculation of the fluid in the fluidic system.

In another embodiment, FIG. 25 depicts the top view composite image of a multilayer device (110) containing two controlled dosing fluidic networks with pumps, valves, debubblers, detection wells, and pressure relief structures. The output of each network feeds one of the inputs of the other network, and without the pressure relieving structures the emptying of an inlet well would cause suction in the outlet of the opposing fluidic network, thus potentially causing bubbles to form in the detection zones. The top two buttons allow pumping of fluid from their respective inlet wells and provide one-way valves to prevent back flow when only one pump is actuated at one time. The bottom two pumps are configured to provide a controlled volume of injected fluid from the inside well into that of the fluid that is pumped through the network from the other well, in similar manner to flow injection analysis techniques. In detail, when actuated the in-line pumps (111) and (112) pump fluid through the one-way valves (113a or 113b) which prevents backflow into the either pump. Actuation control over the pumps (111,112) determines the ratio of the two fluids pumped from their respective input wells (114,115). Gas is removed from the fluid pumped passed the debubbler (116a). The debubbled fluid is then pumped through the detection chambers of (117a), past the pressure relief valve (118b), and then to the inlet well (119) of in-line pump (120). The inline pump (120) is then used to move the carrier fluid that is pumped though the one-way valve (125b), through the common injection chamber (121), past the actuation stop valve (122b), through the debubbler (116b), pressure relief valve (118a) and exits to the well (114). One-way valve (125a) prevents flow of the carrier fluid into the inline pump (123), and the actuation stop valve (122b) is actuated with the inline pump (120) to prevent fluid flow through to the well (124) during this actuation cycle. When inline pump (123) is operated the fluid in well (124) is recirculated through the one-way valve (125a), the injection chamber (121), the open actuation stop valve (122b), and back to the well (124). During this actuation cycle the one-way valve (125b) prevents flow into the pump (120), and the actuation stop valve (122a) is activated to prevent fluid flow to the debubbler (116b).

In one embodiment the onboard pumping and valving of the device is actuated from external pneumatic instrumentation with a configurable pneumatic interconnection provided by the card (126). The configuration provides a robust and very flexible platform that can be configured to take cards for a variety of different applications because the card configures not only the internal valve and pump set-up but also the external valve connections (131). FIG. 26 illustrates the plan (FIG. 26a) and side views (FIG. 26b) of an example device where a common chamber (127) above the pumping areas (128) is pressurized (positive and negative) through a port (130) from an external pressure source to provide a common pumping action to all the pumps under that common pressure chamber (127) (more than one pressure chamber may be used and operated independently). Fluid movement inside the card is allowed or disallowed based on the valving configuration internal to the card that is controlled pneumatically by the external instrument valves (129). Pressure to internal valve structures is controlled from the external valves (129) and can be positive, negative, or atmospheric pressure due to their connection (131) to the pressurized pumping chamber (127) and atmosphere, which is configurable by the card. The instrument valves (129) connect to the card via the ports (132) through a sealing gasket (133).

The present invention also comprises a variety of fluid-handling structures containing deformable components that may be used as pumps or valves. The deformable component may be deformed into a fluid-handling structure, or act upon part of a fluid handling structure, to produce a restriction of flow or an increase in pressure.

Either a portion of or all of the fluid-handling structure may be deformed. This restriction can be used to control fluid movement in a stationary singular valve, multiple valve, or in a moving valve operation, see FIG. 27(a), FIG. 27(b) and FIG. 27(c) respectively. In FIG. 27 the channel is defined by the substrate (203) and deformable material (202). In FIG. 27(a) a single bearing (201) is moving perpendicular to the channel (204) length, deforming an elastomeric material (202) and thereby sealing a part of the channel (204). In FIG. 27(b) three bearings (201) are deforming a deformable material (202) into the channel structure (204) to form a peristaltic type pumping action by alternating their actuation into and out of the channel. In FIG. 27(c) a bearing (201) is moved along the channel (204) length, deforming the deformable material into the channel (204), to push fluid in the channel in the direction of the bearing movement.

According to one embodiment, an external component contains the actuating parts that are in contact with the fluid handling component enabling deformation of part of the channel, causing the channel to be pinched off, thereby allowing valve operations to be performed by causing the channels to be open (FIG. 28) or closed (FIG. 29).

FIG. 28 shows various embodiments of the invention, prior to actuation, that use a combination of deformable (205) and non-deformable (206) materials to produce a fluid-handling structure (208). The deformable material may be an elastomer (205), as shown in FIGS. 28(a) to 28(h), or other material (207), as shown in FIGS. 28(m) to 28p) that changes shape under a stimulus such as applied pressure. FIGS. 28(i) to 28(l) show examples of how combinations of deformable material (205, 207) may also be used to form fluid handling structures (208).

FIG. 29 illustrates the deflection of the deformable material (210) upon actuation (209) into various fluid handling structures. A diverse range of external actuators can be used alone or in combination. They should preferably be appropriately dimensioned to cause the most effective deformation upon actuation. An example would be a circular bearing deflecting a deformable material into a semi-circular channel. An alternative approach, shown in FIGS. 29(c) to 29(f), is to shape, and or confine, the deformable material to ensure that the material (210) deflects into the fluid handling structure upon actuation (209).

The deformable material according to this aspect of the invention may be of any suitable type. One preferred embodiment comprises a deformable material which is an elastomer. Preferably, the deformable material is resilient so as to turn to its pre-deformation shape and position once a stimulus to deform has been removed. Thus, for example, a deformable elastomeric material which is depressed into a channel with an actuator would most preferably automatically return to a position which is outside the channel after removal of the actuator.

In another embodiment the deformable material is a bi-stable or astable material such as a polymer or composite metal that can change shape from a predetermined geometry to another predetermined geometry, and may then return or be encouraged to return to the original state and position once the stimulus has been removed or reversed. Such examples can include button type actuators, either manually, thermally, electrically or mechanically operated, that have been suitably formed into raised or relief structures.

The fluid-handling component may be made of a single shaped substrate or multiple substrates. The fluid-handling structure may be formed into the bulk of a substrate or formed by the definition of several layers of substrate.

The fluid handling structure (211) may be partially or wholly formed inside the deformable material (212), as shown in FIG. 30. FIGS. 30(a) and 30(b) illustrate a deformable material (212) containing fluid handling structures (211) partially defined by a substrate (213). In FIG. 30(a) the deformable material (212) is on the surface of the substrate (213), whereas in FIG. 30(b) the deformable material (212) is interfaced into the substrate (213). FIGS. 30(c) and 30(d) illustrate the fluid handling structure (211) formed within a deformable material (212) and sealed by another deformable layer (212), whereas in FIG. 30(d) the fluid handling structures (211) are formed entirely within the deformable material (212).

The deformable material may be a membrane thinner than the deflection distance, or a bulk deformable material where the depth of the deformable material is larger then the deflection required. A larger deformable material provides advantages for simplifying the actuator mechanism by allowing a larger applied pressure zone, which may induce deformation into smaller structures.

The deformable material may be on the outer surface of the fluid-handling component or within the fluid-handling device.

The deformable material may cover the entire surface or part thereof. For example, it may include gasket or o-ring geometries.

The deformable material may be flush with the surface or extend above the surface of the channel.

The deformable material may deform into one or more fluid-handling structures.

In another embodiment multiple stationary valves formed from the deformable material may be used to induce fluid flow by alternating their on/off states to produce a peristaltic type motion (FIG. 27(b)).

The deformable or microfluidic structure may be combined with other fluid restricting elements, such as diffuser nozzles or valves, to form pumps or part of a pumping mechanism. These valving structures may be disposed proximally to the pumping chambers, as indicated by the arrows in FIG. 28(o) and FIG. 28(p), or along the length of the pumping chamber or channel. Valves disposed along the length of the channel may include directional flow inhibiting structures, such as graduated channel restrictions or one-way valves. FIG. 31 illustrates a channel (217) formed in a substrate (215) with a contoured surface providing a one-way valving action upon deflection of a deformable material (214). In this example, a roller bearing (218) moving in the direction of the arrow pushes fluid (216) along the contoured surface (217) in front of the bearing. The build up of fluid pressure in front of the bearing deflects the membrane (214) forcing the fluid (216) along the contour.

According to another embodiment, movement of an actuator that induces deformation in a fluid-handling structure may create a pumping action by inducing a wavelike motion that forces fluid to flow along the channel. FIGS. 32(a) and 32(b) provides a schematic representation of pumping zones produced from linear (220) and radial (221) actuator movements along the surface of a fluid-handling device to induce fluid flow (219). FIG. 33 depicts the top view of a multilayer device using the radial pump (224) configuration connected to microfluidic channels (225) leading to three valve locations (222) and inlet/outlet ports (223). As the deformation of the elastomer travels the length of the channel, then in many cases valves are not required to stop backflow as the deformation into the channel is maintained.

These particular embodiments use a mechanical actuator to apply pressure onto the deformable channel structure perpendicular to the channel direction, and zero or low force parallel to the deformed substrate layer to reduce frictional forces. The deformable substrate(s) may be an integral part of the microfluidic chip, whereas the rotating part or actuator may be a part of an attached or accompanying instrument or such controlled device. Examples of mechanical actuators are shown in FIG. 34, and may for example include spherical objects (227) and bearing assemblies (228), pins and pistons (226), wobble boards (229), cams (230), and wipers (231). Other desirable embodiments may include manual actuation such as with an operator's finger, or by use of energy applied by instruments or devices containing electrostatic, electrical, resistive, light, piezo-electric, electromagnetic, pneumatic, hydraulic, linear and magnetic force actuators. The example shown in FIG. 35 depicts an exploded view of a radial bearing pump with two actuator heads used to deform the elastomeric layer for the device depicted in FIG. 32. One bearing head assembly is used to perform a pumping action while the other operates nearby valves. The bearing assemblies consist of spherical objects (234) contained within housings (232) mounted onto gear assemblies (235, 236) connected to a drive rods (238). The whole assembly translates drive rotation 90 degrees to rotate the bearing assemblies, and is held together with fixing pins (233) joining the housing (237) together.

### Optical Measurement Devices and Methods

The following description of certain preferred embodiments focuses on light as the electromagnetic wave used in the device. However, the person skilled in the art will appreciate that certain embodiments are equally applicable to other electromagnetic waves.

A purpose of an optical fluid detection cell is to guide light rays in or out of the channel to improve detection sensitivity and therefore improve detector response when analyzing fluids, and materials processed by fluid flowing through or contained within the cell. The structures, devices and methods disclosed herein are both applicable to measuring longitudinally and transversely inside fluid detection cells.

For analyzing the incident light after it has traversed a fluid contained in a detection cell, analytical methods include, but are not limited to, in-channel colorimetric, luminescence (phosphorescence and fluorescence), absorption, and transmission.

The fluid in the detection cell may be stationary or moving.

The molecules being analyzed may be anywhere within the channel, for example, they may be within the fluid, bound to the detection cell walls, or attached to another substance within the detection cell.

Off-chip optical elements such as lenses and filters may also be used to focus and condition the rays of light incident to or transmitted from the device.

A device according to the present invention may incorporate any known electromagnetic radiation transmissive, reflective, refractive, modifying, or splitting component. Examples of these include, but are not limited to, the following absorbing, reflective, refractive, or diffractive components as singlets or part of multiple optical elements; diffusers (from material inhomegenity, surface microstructuring), lenses (concave, convex, spheric, aspheric, fresnel), prisms (for guiding or separating light, beamsplitters, collimators), refractive surfaces (materials with different refractive indexes, moths eye microstructuring to reduce reflections at surfaces), surface coatings for refractive index changes (optical coatings such as thin metallic layers), diffractive gratings, reflectors (planar, spheric, aspheric, Fresnel, corner cube) and filters (absorbing, dichroic, binary).

According to one embodiment the device is a multilayer device, and the bulk of the device is partially or entirely polymeric. The fluidic or optic components may be made by removing or displacing material in the bulk or cutting entirely through a layer. Devices according to the present invention can be fabricated by either batch, serial, or continuous manufacturing techniques. Such techniques include, but are not limited to, embossing, injection molding, stamping, roller cutting, plasma or chemical etching, laser processing, and thermoforming.

In one embodiment, either or both of the light source S and detector D can be located perpendicular to the fluid carrying channel. FIGS. 36(a) to 36(d) show top views of microfluidic channels (401 & 402) with transmission windows (301) on the top surfaces for illumination and or detection. In theses examples the detection zone is located longitudinally through the microfluidic channels (402) between the transmission windows (301).

Cross sections of devices with longitudinal detection zones are shown in FIGS. 37(a), (b), and (c) where photon-redirecting elements are used to guide the electromagnetic radiation through the device. S and D refer to Source and Detector (of light) respectively. FIG. 37(a) shows angular reflective (412) surfaces at either end of the channel (403) which redirect the photon path (302) through wave guides (301) in the device (303) between essentially vertical and horizontal directions. FIG. 37(b) illustrates an example where angular reflective surfaces (412) are used to guide the photons within a device (303). The photon path (302) may traverse fluidic and non-fluidic waveguides (404, 406) and pass between layers within the device by redirecting the light through transmissive windows or ports (405) between layers. Devices may also incorporate prismatic structures to guide photons within the devices. An exemplary device (303) incorporating prismatic or refractive structures is shown in FIG. 37(c). In this example a fluid filled detection channel (304) has angular end walls to guide the photon path (302) through the top layer of the device, along the detection channel (304), and out through the bottom layer.

In one embodiment, reflective components (either mirror surfaces or higher refractive index materials) are added to the walls of the microfluidic channel to avoid losses through the channel walls. FIGS. 38 and 39 provide examples of fabrication steps for fabricating the reflective components in the microfluidic channel by reflective film deposition. FIG. 38 illustrates four steps in fabricating a 3-layer device by cutting entirely a layer (305) to produce a void or fluidic channel (307). The coatings (306) are added prior to bonding the layers together or after an intermediary step, bonding some of the layers before finally sealing the coated microfluidic channels (408). Whereas FIG. 39 illustrates the fabrication steps of a 2-layer device shaped by techniques such as embossing or injection molding followed by reflective layer deposition and then assembly. In this example, structuring and coating is performed on the substrate layer(s) (305) prior to assembly to produce the coated microfluidic channel (407). Reflective films (306) may be deposited after structuring as with sputtering and chemical vapor deposition, or by methods such as hot-stamping (as is often used in the printing industry for decorative coatings). Hot stamping provides the deposition of a relatively thick metallic film, and in some cases complex multilayer structures, in a simple stamping process that is easily integrated into continuous manufacturing strategies such as web-based or reel-to-reel production. Hot stamping can be performed prior to or after an embossing or lamination process to further structure or coat the deposited film.

In a further embodiment light pipes, or waveguides, are created within the device to guide light rays to the detection cell, and in some cases along the length of the detection cell. The cross sections illustrated in FIGS. 40(a) and (b) show embodiments of detection cells with coated channels for increased internal reflection. FIG. 40(a) shows an example of three substrate layers (309) forming a microfluidic waveguide (409) with reflective surfaces (308). Photons that are approximately perpendicular to the top or bottom surface and proximal to the angular surface structures in the microfluidic channel are guided longitudinally along the channel length, and reflected at the other end of the channel to exit through the surface opposite to the entry surface. FIG. 40(b) shows an example of 4 substrate layers (310) combined in a way to provide a waveguide through multiple layers. In this example the waveguide structures (410) have reflective surfaces (311) and may be made from voids within the layers. These voids may be vacant or filled with transmissive materials. The coatings may also be applied to surfaces on layers not in contact with the waveguide or fluidic structure (313), as shown in FIG. 40(c) where a reflective (312) layer is provided on the bottom substrate surface to allow incident radiation approximately perpendicular to the top surface to be reflected after passing through a microfluidic channel or void (314).

Dichroic, absorption and other filters may also be incorporated, for example by coating a surface of one or more of the layers of the device.

In other embodiments different refractive components are incorporated including, but not limited to, prisms and materials with different refractive indexes. FIG. 41(a) shows prism (411) and lens (319) structures embossed into a layer before bonding to form a three layer (315) microfluidic device. In this example incident photons (317) are guided through the prism structure into two opposing microfluidic channels (316), then reflected at either end of the channel and focused external to the device by concave lens structures (319). Reflective layers or coatings (318) are used for improved photon yield. A similar structure is illustrated in FIG. 41(b) where a three layer (324) microfluidic device incorporates concave (320) and convex (325) lenses to focus the photons (322), and reflective surfaces (321) to guide the photons through the void or fluidic channel (323). FIG. 41(a) and (b) incorporate lenses on the top surface of the device to help focus the light rays. Whereas FIG. 41(c) incorporates lens components inline with the detection cell to either focus the light within the device, such as into a waveguide, or to or from external components. In this example a 3-layer substrate (326) device is shown with a concave (331) lens to focus incoming radiation and a convex lens (327) for focusing radiation once it has traversed the detection cell. Reflective surfaces (328) are used to minimize photon (329) losses along the channel (330) walls.

According to another aspect of the invention, integrated lens components can be fabricated in single or multilayer systems. These lens systems may be either in-plane or out-of-plane with the microfluidic channels. In many cases this allows simple fabrication of the lens components with the same method used for forming the channel.

Other embodiments can include the light-transposing elements outside the fluid carrying channel, or detection cell. For example, FIGS. 41(a), 41(b), and 41(c) demonstrate lenses fabricated in the same part as the fluid detection cell, but not integral to the fluid detection cell. Other lenses, such as Fresnel or aspheric, may be equally well used.

Multiple lens systems may also be fabricated within the device to improve light guidance, see FIG. 42. This example illustrates a multi-lens element for collimating radiation (335) consisting of convex (333) and concave (334) components inline with the channel or void (332).

Certain embodiments use optical fibers, which may be used with or without additional lens components for improved signal coupling. FIGS. 43(a) and (b) illustrate microfluidic devices (336) with individual fibers (338) arranged longitudinally to a microfluidic channel (337). Bundles of optical fibers may also be employed and in certain preferred embodiments the fibers are terminated externally to the fluidic part. In one such example, FIG. 43(c) illustrates a tapered fiber optic bundle (340, 341) located proximally to a microfluidic device (339) for signal capture and or illumination.

Other prismatic and reflective structures can be used focus or guide the photons for improved signal response. For example corner cube reflectors, as shown in FIG. 44, provide parallel light return and can be used for both increased exposure and signal capture. FIG. 44(a) provides a schematic view of a single corner cube cell (342) reflecting radiation (343) parallel to the incident path. Similarly, FIG. 44(b) represents a cross section of a corner cube array (344) reflecting incident radiation (343). Reflectors may be located transversely or longitudinally in the microfluidic device either in the fluid channel or proximal to the fluidic channel, for example, FIGS. 45(a) shows longitudinally located reflectors formed at the ends of microfluidic detection flow cells with reflective walls. Indication of fluid flow direction through the detection cell is provided by (347). Radiation (346) incident to the surface is collimated by surface structures (349) before passing into fluidic channels having reflective walls and corner cube ends (345). The radiation (346) is then reflected back along the detection cell and out of the device (348). An alternative approach is illustrated in FIG. 45(b) where a fluidic device (350) incorporates a reflector array (354) that is located transversely to the detection cell (352). Radiation (351) is firstly collimated by parallel surface structures (353), it then traverses across the flow channel, and then is reflected on a proximal return path. The reflectors (358) may also be located externally to the microfluidic device as shown in FIG. 45(c), simplifying the device fabrication. In this example a 3 layer microfluidic device (355) incorporates a detection cell (356) located proximally to the reflector array allowing radiation (359) to pass entirely through the device (355) before reflection.

Collimators (349, 353, 357) are used to help guide the radiation so that the photons are approximately parallel and normal to the surface.

Similarly, other combinations of reflectors and prismatic surfaces can improve photon density by guiding radiation. FIG. 46 depicts ray tracing examples of prismatic and collimating surface structures, respectively. Both techniques can be used to provide a more collimated beam, and when combined with other structures can lead to an improved signal response. FIG. 46(a) depicts a prismatic array on a substrate surface (361) that refracts or reflects radiation (360) depending on the incident angle, enabling control over radiation exit angle. FIG. 46(b) illustrates surface structuring (362) with walls normal to the substrate surface (361) to collimate incident radiation (364). Refraction or internal reflection on the structure walls (362) provide collimated radiation output (363).

Some examples of where prismatic or collimating surface structures may be used in a fluidic device are shown in FIGS. 47(a) to (j). These structures are illustrated as 2-layer substrate devices but are equally applicable for other multilayer devices. These structures may also be used in the cases of single layer devices, such as microscope slides, where the surfaces of the slides or coverslips are patterned. An example of which would be the use of corner-cube reflectors on the underside of a microscope slide to enhance microarray and other fluorescent imaging on the slides opposite surface, by only reflecting beams that are largely perpendicular to the slides surface. The detection cell or void (371) can be a part of a fluidic network and is depicted here as either a transverse or longitudinal cross-section. The structured (365), and or reflective (366), surfaces are provided for guiding photons either transversely, longitudinally, or both transversely and longitudinally through the fluidic channel.

FIG. 47(a) illustrates the use of collimating structures (365) located proximally to a fluidic channel (371). This reduces photon loss from scattering and random emission by collimating the photons passing through these surface structures.

FIG. 47(b) illustrates the use of collimating structures (365) located proximally to a fluidic channel (371) with reflective walls (366). In this example photons entering the channel at the ends of the collimated structures (365) are reflected by the angled walls to travel inside the channel (371). The reflective walls (366) improve photon containment within the channel (371). The photons exit the channel (371) proximal to the reflective angled walls at the ends of the channel where the photons are again collimated by (365) while leaving the device. This method is not suitable for imaging segments of the channels (371) but improves photon yield when acquiring data from the entire channel (371).

FIG. 47(c) illustrates the use of prismatic structures (367) inside the channel (371). These structures (367) may also be used to help collimate the photons passing through their structure by reflecting photons that are of too large an incident angle to the normal of their surfaces. Therefore the angle of the prismatic surface structures determines the photon acceptance angle. This can be particularly useful for improving the signal-to-noise response in applications such as luminescence by separating the excitation and emission photons. Collimated excitation photons incident normal to the structured surface are reflected while a portion of the random emission photons pass through the prismatic structures.

In FIG. 47(d) reflective surfaces (366) can be added to improve photon yield by reflecting photons back across the channel (371). As shown in FIG. 47(e), these surfaces may also be in the form of structured reflectors (368) such as corner cubes, spheric, or aspheric reflectors. By making the reflectors a part of the channel surface, as shown in FIG. 47(f), photon losses at material boundaries are reduced and in some applications materials can be attached within the structures for improved point source imaging, as with microarray or microsphere imaging. However placing the surface structure within the channel is unsuitable for some applications as it hinders fluid interactions, and may also require a more distant focal center.

FIGS. 47(g) and 47(h) include prismatic layers (367) proximal to and on the surface of a channel (371), respectively. In FIG. 47(g) the addition of the reflective layer (366) with the prismatic structure (367) provides a collimator that improves photon yield by reflecting the photons passed through the prismatic structures (367).

Lenses may also be combined within the structures to focus light into or from the fluidic device. The examples in FIGS. 47(i) and 47(j) illustrate devices incorporating aspheric (369) and Fresnel (370) lens types, respectively.

The example in FIG. 48 provides photon path tracing (372) for both longitudinal illumination and point source imaging (377). Incident light from a source is focused by an aspheric lens (376) onto a reflective wall (375), this turns the photon path 90 degrees along the channel length to illuminate point sources. The excitation photons that pass through the channel (373) are then reflected at the wall on the opposite end of the channel and focused externally through a lens (376). Point source emissions inside the channel may be reflected by (375) and collimated (374) for improved signal response. This combination of using longitudinal with transverse photon guiding elements, some examples are shown in FIGS. 47 and 48, has many advantages;
This configuration can provide a single detector cell that is suitable for most types of photon detection methods. For example many techniques require either an increased path length for high-resolution solution based analysis, or require imaging of along the channel length.
Different detection methodologies can be combined for multi-parameter measurement. For example for fluorescent microarray analysis the longitudinal absorption measurements can tell the introduction of certain reagents, or detect the presence of bubbles, whereas the luminescent point sources under analysis are imaged transversely.
An improved signal to noise ratio is achieved in many cases, particularly important for luminescent based measurement, where the excitation and emission wavelengths are close. Interference from the excitation wavelength can be minimized by exciting longitudinally and detecting transversely.
Packaging miniaturized instrumentation is simplified in some cases where the detector and source are located on the same side of the device.

In one embodiment detector and source zones are located proximally on a device. FIG. 49(a) illustrates such an example in a device (378) where photons (383) enter a transparent zone (379), where the photons may be conditioned before they are reflected longitudinally, and exit through another transparent (380) zone. Such conditioning may include gratings, prisms, fluorescers, luminophores, or filters that alter the spectral content or shape of the wave beam. The longitudinal reflection may be performed with an external waveguide (381), as shown in FIG. 49(b), or within the device with an internal waveguide (382), as shown in FIG. 49(c). Advantages of having the light path (383) travel through a light conditioning element on the device in this manner is that the card can be designed for the specific application requirements. This enables an instrument to operate a variety of inserts or devices without having to change the instrument optics.

FIGS. 50(a) and 50(b) illustrates further embodiments for the fabrication of waveguides. A waveguide operates by reflecting, or transmitting, incident light at a material boundary. In the past typical fabrication methods in microfluidic devices have involved using the entire planar material, inserting a fiber optic directly into the sensor system, or lithographically patterning the surface in a similar manner to the fabrication of semiconductor devices. In this example of FIG. 50(a), a refractive material (387) is applied to a preformed channel (384) in a fluidic device (385) using a suitable tool (386). The refractive material is then cured to form the cured and formed reactive waveguide (388) within the fluidic device. In FIG. 50(b) preformed waveguides (389) are slotted into a fluidic device (390). The contained waveguides (393) are then sealed with a containment layer (391) to produce a combined waveguide and fluidic device (392).

A method for improving the wave-guiding properties of a transparent material is to increase the difference in refractive indices at the material boundaries. Changes to the surface properties at these boundaries can induce refractive index changes for improved reflection or transmission. In particular deposition of thin films can provide improved surfaces for waveguides and reflective surfaces, for example, deposition of a thin (a few tens or hundred of nanometers) silver coating to provide a negative refractive index.

To guide electromagnetic energy in complex geometries, channels can be formed with pre-structured layers. The channels formed may then be filled if required. These structures may either be filled by; injecting and then curing a transparent material, or placing an already formed wave guide into the vacant structures, as shown in FIG. 50.

### Methods of Instrument Configuration

The present invention also provides methods whereby all, or some, of the upgrade information, operational data, or software architecture for an instrument can be contained within or on an insert, whereby the instrument may contain some or all of the software modules for templates and basic program operation but does not contain all data that is required to operate the instrument in full, some of this data being provided by the removable inserts. The inserts can be recognized upon connection to the instrument and the program operation is performed according to the data coded into one or more inserts.

The inserts may or may not be primarily used for other purposes necessary for the normal operation of the instrument such as a SIM card for a mobile telephone or a microfluidics chip for an analytical device. The inserts are recognized upon insertion into the matching instrument and the functional program of the instrument is performed according to the cooperation of the functionality of the instrument and the data coded into the insert(s).

In one embodiment the insert contains access or authorization information allowing the user to access certain functions or features of the instrument, such as new application and protocol data, user settings, device characteristics or functionality.

In another embodiment the present invention provides improved user operability and operational automation from the insert providing data to the instrument to automate parts or all of the application operation and provide user defined settings, thereby simplifying user interaction, which improves system reliability and simplifies instrument operation.

In another embodiment the insert contains access or authorization information allowing the user to access remote features. These remote features can include internet sites for upgrade, experimental or application information, or local area networks for instrument and computer system access.

Embodiments of the invention may include data contained within the insert relating to the insert's or instrument's use. This data can be stored on the insert during the time of manufacture and may contain user, experimental, instrument and application information. Examples of this type of data include factory settings, calibration information, user information, device usage, collected data, sensor data, settings, sampling or operational location information (for example, GPS tracking of samples), time and date stamps, production data and quality control, tracking, and other information that may be used by the instrument, user or the manufacturer of the instrument/device/insert.

In another embodiment the data may be written to, or updated, in the field by the user or the instrument prior to, during, or after use. This field written information may also contain user data, sampling or operational location information input by the user or by the instrument from a global positioning system, results, instrument settings, experimental conditions, application information, and other user or instrument data.

In another embodiment the insert contains information for user profiling. Allowing the user to automatically configure the instrument based on the user's personal settings, or teaching the instrument about operations the user typically performs or requires. This can be performed directly by instructions on the insert, or through learning algorithms on the instrument's software analyzing either the current user's, or another user's, previous operations.

One embodiment of the invention describes an instrumentation and insert architecture in which one or more inserts become a part of the software upgrade path for the instrument, more specifically, the insert or inserts contain the upgrading information. An example of which is shown in FIG. 53. This approach of integrating the new software information onto the insert allows the instrument to now accept new insert applications, calibration or program data without the need for the user to upgrade the software via other media, thereby simplifying user operation and reducing manufacturer overheads. A further advantage of having the upgrade data with the consumable insert is the added security feature of requiring the matching instrument with the correct interface to connect to the matching insertable device.

Another embodiment of the present invention provides operating system software that is structured with core machine management functions and inbuilt application specific templates, which are controlled by the insert to configure the instrument to meet market or customer needs as and when required.

In one embodiment an Object Orientated approach is taken in which the instrument contains the programming subroutines and functions to perform all the common and low level operations, such as acquiring data, selecting acquisition channels, pumping, switching valves, setting temperatures, template GUIs etc. In one embodiment, the generic subroutines in the instrument are operative to perform one or more of the following actions: acquire data, select acquisition channels, control pumping, control valve switching, set temperatures, graphical user interface configuration, and one or more of program code, data or commands of the insert enable instrument operation for a particular application.

One or more inserts contain the application's specific calls and variables to the instrument's subroutines and functions. This approach is represented by the example shown in FIG. 54. This approach allows the inserts to control the instrument's operation and GUI for the insert's particular application. Examples of program flow can be seen in FIGS. 55 and 56 where an insert starts the application programs and passes, or enables to be passed between programs, operational data or variables to effect a function by the instrument.

In another embodiment a non-object orientated approach can be taken in which the instrument contains the program code to perform all common and low level operations, such as acquiring data, selecting acquisition channels, pumping, switching valves, setting temperatures, template GUIs, etc. One or more inserts contain the code and or variables to enable the instruments operation for the inserts particular application. This approach allows the inserts to control the instruments operation and GUI for the inserts particular application.

This distributed architecture (e.g., FIG. 54) minimizes the software development associated with new application development for an instrument and its associated inserts. The generically programmed instrument can then accept new applications without the need for the user to upgrade the software.

Furthermore, the invention provides extra software security as the program execution instructions do not exist in the instrument. With the inserts carrying only the instructions to configure the instrument for that particular insert's specific application. This method provides a much more difficult path to reverse engineer as a full understanding of the program's execution is required. If an instrument and an insert's interaction is reversed engineered, then the resultant program execution reveals only data for that specific application for which the insert was fabricated.

It is a further object of this invention that the information or data contained within inserts may be either or both, written to or read from.

According to another embodiment the insert may transfer all of its operational coding to volatile memory on the instrument, retaining only its identification and data storage and data reading functionality, thereby making it a “one use only” device and all operational coding is destroyed once the insert is removed from the instrument. This prevents unauthorized access to the proprietary coding contained in the insert as it can only be read by the matching instrument and it only exists in volatile erasable memory of that matching instrument while the insert is inserted and is automatically erased permanently once the instrument is switched off or the insert removed or the operational program is completed, whichever occurs first.

The inserts described herein may be either singular or multiple. The inserts may be a removable memory device, such as Flash Disks, sensors or microfluidic cartridges. The data on the inserts may be stored in many different formats, including but not limited to, barcodes, onboard memory, microprocessors and other integrated circuits, electrical interconnects or resistivity, radiofrequency, optical, mechanical or electromagnetic formats.

The foregoing descriptions are specific embodiments of the present invention, particularly those related to microfluidics. It should be appreciated that such embodiments are described for purposes of illustration only, that numerous alterations and modifications may be practiced by those skilled in the art without departing from the spirit and scope of the invention. It is intended that all such modifications and alterations be included insofar as they come within the scope of the invention as claimed or the equivalents thereof.

Throughout this specification (including any claims which follow), unless the context requires otherwise, the word ‘comprise’, and variations such as ‘comprises’ and ‘comprising’, will be understood to imply the inclusion of a stated integer or step or group of integers or steps but not the exclusion of any other integer or step or group of integers or steps.

### REFERENCE NUMERALS IN THE DRAWING FIGURES

01 Actuation component
02 Fluidic Channels
03 Actuation Area
04 Injection Pump Symbol
05 In-Line Pump Symbol
06 On/Off Valve Or Variable Flow Valve Symbol
07 One Way Valve Symbol
08 Actuation Area
09 Inline Pump
10 Fluidic Channels
11 Injection Pump
12 On/Off Valve Or Variable Flow Valve
13 In-line pump actuated on opposite actuation cycle to other inline pump
14 Actuation Area
15 Fluidic Channels
160 On/Off Valve Or Variable Flow Valve
17 In-Line Pump
18 Injection Pump
19 Actuation Area
20 Fluidic Channels
21 In-Line Pump
22 On/Off Valve Or Variable Flow Valve
23 Stream of fluid
24 Stream of fluid
25 Stream crossover/intersection point
26 Injector pump and two valves in same actuation area
27 Injector pump and two valves in same actuation area
28 Inline Pump
29 Inline Pump and two valves in same actuation area
30 Stream of fluid
31 Stream crossover/intersection point
32 Stream of fluid
33 Actuation Area
34 One Way Valves
35 Membrane stop valve
36 Deformable Membrane
37 Inlet Fluid flow
38 Outlet Fluid flow
39 Inlet port with Applied force
40 Deformable Layer
41 Debubbler
42 Vent With Check Valve
43 In-Line Pump
44 Injection Pump
45 Gas
46 Semi-permeable Membrane Or Vent
47 Fluid flow
48 Gas flow from pressure gradient
49 Substrate
50 Vent
51 Inlet Port
52 Fluidic Channel
53 Chamber
54 Fluidic Channel
55 Layered Device
56 Vent
57 Vent Chamber
58 Semi-permeable Membrane Or Vent
59 Gas Bubble
60 Regulating valve
61 Venting chamber
62 Deformable Membrane
63 Semi-permeable Membrane Or Vent
64 Fluid chamber
65 Air passage
66 Deformable structure
67 One-way Valve
68 Semi-permeable Membranes
69 Pressure Relief Valve
70 Fluid Reservoir
71 Fluidic Channel
72 Semi-permeable membrane
73 Gas Flow Path
74 Fluid Flow Path
75 One Way Valves
76 Applied pressure gradient
77 Fluid Flow in pump chamber
78 Semi-Permeable Membrane
79 Applied pressure gradient
80 Fluid Flow
81 Semi-permeable membrane
82 Conductive Material
83 Hole in substrate layer
84 Deformable Actuation Structure
85 Fluid flow direction
86 Semi-permeable membrane
87 Deformable Actuation Structure
88 Pressure Relief Valve
89 Actuation direction of deformable structure
90 Actuation volume
91 Fluid Pumping Chamber
92 Inlet port
93 Inline pump
94 Debubbler
95 Detection chamber
96 Direction Of Fluid Flow
97 Pressure relief structures
98 Fluidic Channel
99 In-line Pump
100 One Way Valve
101 Sample Introduction with one way valve
102 Actuation Area
103 Debubbler
104 One way valve pressure relief valve
105 Split flow Mixer
106 Detection Chambers
107 Pressure relief structure
108 Sample Introduction Port with semi-permeable membrane
109 Air return
110 Multi-layer fluidic device
111 Inline pump
112 Inline pump
113 One-way valves
114 Fluid storage well
115 Fluid storage well
116 Debubbler
117 Detection chambers
118 Fluid pressure relief structures
119 Fluid storage well
120 Inline pump
121 Injection Chamber
122 Actuation stop valve
123 Inline pump
124 Fluid storage well
125 One-way valves
126 Fluidic Card
127 Pressure chamber
128 On-card Pumps
129 Instrument Valves
130 Pressurization port
131 External valve interface
132 Valve interface port
133 Gasket
201 Ball Or Roller Bearing
202 Flexible Wall
203 Rigid Substrate
204 Fluidic Channel
205 Elastomer material
206 Non-deformable substrate
207 Deformable material
208 Fluidic Channel Or Chamber
209 Direction Of Applied Force
210 Deformable Material
211 Fluidic Channels
212 Deformable Material
213 Substrate
214 Deformable Material
215 Substrate With Suitable Restrictions Or contoured surface
216 Flowing Fluid
217 Fluidic Channel
218 Bearing
219 Direction Of Movement And Flow
220 Linear pumping zone
221 Radial pumping zone
222 Valve Locations
223 Inlet/Outlet Ports
224 Radial Pumps
225 Fluidic channel
226 Rod Like Driving Mechanism
227 Spherical Objects
228 Rotating Housing
229 Rotating Platform (Wobble Board)
230 Rotating Cams On Rod Structure
231 Rotating Wiper
232 Rotating Housings
233 Fixing Pins
234 Spherical Objects
235 Drive Gears
236 Drive Gears/Motor
237 Solid Fixing Base
238 Drive Rods/Bearings
301 Transmissive Windows
302 Photon Pathways
303 Fluidic Device
304 Detection Channel
305 Individual Substrate Layers
306 Reflective Layer or Coating
307 Cut-Out or Void In Layer
308 Reflective Layers or Coatings
309 Individual Substrate Layers
310 Individual Substrate Layers
311 Reflective Layers or Coatings
312 Reflective Layer or Coating
313 Individual Substrate Layers
314 Void or Fluidic Channel
315 Individual Substrate Layers
316 Void or Fluidic Channel
317 Photon Pathways
318 Reflective Layers or Coatings
319 Concave Structure
320 Concave Structure
321 Reflective Layers or Coatings
322 Photon Pathways
323 Void or Fluidic Channel
324 Individual Substrate Layers
325 Convex Structure
326 Individual Substrate Layers
327 Concave-Planar Structure
328 Reflective Layers or Coatings
329 Photon Pathways
330 Void or Fluidic Channel
331 Plano-Convex Structure
332 Void, Refractive Inclusion or Fluidic Channel
333 Convex Structures
334 Concave Structures
335 Photon Pathways
336 Fluidic Device
337 Void or Fluidic Channel
338 Light Fiber or Wave Guide
339 Fluidic Device
340 End Of Fiber Optic Bundle
341 Fiber Optic Bundle Drawn Into Smaller Diameter
342 Prismatic Structure—Reflective or Refractive
343 Photon Pathways
344 Reflective Surface
345 Reflective Surfaces
346 Photon Pathways
347 Direction Of Fluidic Flow
348 Fluidic Device
349 Collimating Surface Structures
350 Fluidic Device
351 Photon Pathways
352 Fluidic Channel
353 Collimating Surface Structures
354 Reflective Surfaces
355 Fluidic Device
356 Fluidic Channel
357 Collimating Surface Structures
358 Reflective Surfaces
359 Photon Pathway
360 Photon Pathways
361 Device Layer
362 Collimating Surface Structures
363 Collimated Transmitted Radiation
364 Random Incident Radiation
365 Collimating Surface Structures
366 Reflective Surfaces
367 Refractive/Reflective Prismatics
368 Reflective Surface structures
369 Surface Lens Structures
370 Fresnel Lens Structures
371 Fluidic Channel
372 Photon Pathways
373 Fluidic Channel
374 Surface Collimating Structures
375 Reflective Layer or Coating
376 Surface Lens Structures
377 Particles Of Interest In Fluidic Channel
378 Representation Of A Fluidic Device
379 Photon Transparent Region
380 Photon Transparent Region With Photon Conditioning Element
381 External Wave Guide
382 Internal Wave Guide
383 Photon Pathways
384 Preformed Channel
385 Fluidic Device
386 Suitable Tool
387 Refractive Material
388 Cured And Formed Refractive Wave Guide
389 Preformed Wave Guides
390 Partially Complete Fluidic Substrate
391 Containment Layer
392 Completed Fluidic Device
393 Wave Guides In Situ
401 Fluidic Channels
402 Fluidic Channel
403 Fluidic Channel
404 Waveguide
405 Transmission Port
406 Waveguide
407 Fluidic Channel
408 Fluidic Channel
409 Fluidic Channel
410 Waveguide
411 Prismatic Structure
412 Angular reflective surfaces

1-107. (canceled)

108. A fluid handling structure comprising:
an actuation area to enable control of fluid flow within the structure; and
at least one actuation component within the actuation area;
wherein the actuation area is arrange to activate or control the at least one actuation component.

109. A fluid handling structure comprising:
an actuation area to enable control of fluid flow within the structure;
at least one of a fluid chamber or channel;
a semi-permeable membrane forming at least one boundary of the fluid chamber or channel, the semi-permeable membrane arranged so as to permit the passage of a control fluid therethrough and into the fluid chamber or channel, thereby promoting restricting, or stopping fluid flow within the fluid chamber or channel.

110. A recirculating fluid network comprising:
an inlet;
at least one or a pump or valve; and
a debubbler.

111. A plurality of interconnected fluid networks, where at least one of the fluid networks comprise a fluid network optionally constructed according to claim 110.

112. A fluid handling structure comprising:
a fluid channel; and
a deformable material;
wherein the fluid channel is bounded, at least in part, by the deformable material, and the deformable material is arranged to produce a restriction within the channel.

113. A fluidic device comprising at least one channel defining a path for the travel of an electromagnetic wave.

114. An arrangement comprising:
the fluidic device of claim 113;
an electromagnetic energy source; and
an electromagnetic energy detector.

115. A method of performing a function with an instrument, the method comprising:
associating an insert with the instrument, the insert comprising one or more of program code, data, or commands, which enable performance of the function.

116. An insert configured for use with an instrument to perform a function, the insert comprising one or more of program code, data, or commands, which enable performance of the function.

117. A combination comprising the insert of claim 116 and an instrument.

118. A method of updating software or firmware of an instrument, the method comprising: associating an insert with the instrument; and transferring one or more of program code, data, or commands to the instrument thereby effecting the update.
